(19) United States
(12) Patent Application Publication
(10) Pub. No.: US 2010/0327274 A1
(43) Pub. Date: Dec. 30, 2010

(54) ORGANIC LIGHT-EMITTING DEVICE

(75) Inventors: Maki Okajima, Kawasaki-shi (JP); Akihito Saitoh, Yokohama-shi (JP); Masumi Itabashi, Kodaira-shi (JP); Masanori Muratsubaki, Hachioji-shi (JP); Naoki Yamada, Inagi-shi (JP); Hiroki Ohrui, Kawasaki-shi (JP); Chika Negishi, Yokosuka-shi (JP); Tetsuya Kosuge, Kawasaki-shi (JP); Takayuki Horiuchi, Tokyo (JP); Takeshi Sekiguchi, Tokyo (JP); Hiroyuki Tomono, Numazu-shi (JP)

Correspondence Address: FITZPATRICK CELLA HARPER & SCINTO, 1290 Avenue of the Americas, NEW YORK, NY, 10104-3800, US

(73) Assignee: CANON KABUSHIKI KAISHA, Tokyo (JP)

(21) Appl. No.: 12/919,114

(22) PCT Filed: Mar. 31, 2009
(86) PCT No.: PCT/JP2009/057035

§ 371 Date: Aug. 24, 2010

(30) Foreign Application Priority Data
Apr. 1, 2008 (JP) 2008-095106

(51) Int. Cl. H01L 51/54

(52) U.S. Cl. 257/40; 257/E51.027

(57) ABSTRACT

An organic blue-light-emitting device having a high emission efficiency and a long continuous driving lifetime is provided. An organic light-emitting device 20 includes an anode 2, a cathode 5, and a stacked body which is interposed between the anode 2 and the cathode 5 and includes at least a layer which forms a light-emitting region (emission layer 6). The layer which forms the light-emitting region includes at least one of each of below-mentioned compounds (a) and (b):
(a) a first organic compound represented by the following general formula [1] or general formula [2]:

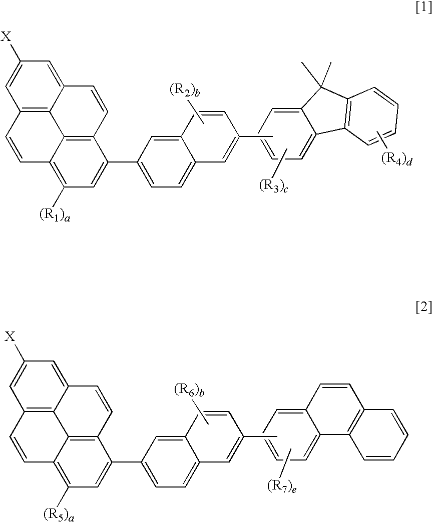

(b) a second organic compound represented by the following general formula [3] or general formula [4]:

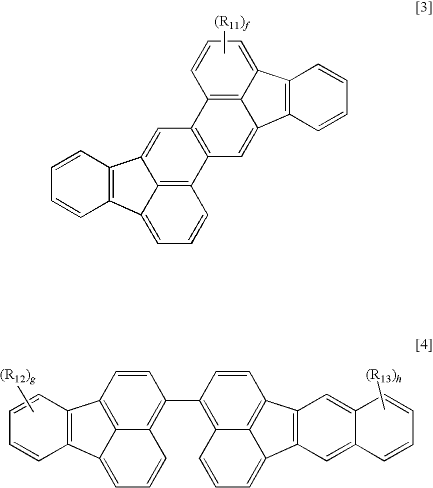

### TECHNICAL FIELD

The present invention relates to an organic light-emitting device.

### BACKGROUND ART

An organic light-emitting device includes a thin film containing a light-emitting organic compound which is interposed between an anode and a cathode. In the device, holes and electrons are injected from the respective electrodes to yield excitons of the light-emitting organic compound and then light is generated from the organic light-emitting device when the excitons return to their ground state.

Recently, there has been a significant progress made relating to an organic light-emitting device. The characteristic feature includes high luminance at a low applied voltage, a variety of emission wavelengths and a high-speed responsivity and that also a thin and light-weight light-emitting device can be produced. From such viewpoint, possibility of using an organic light-emitting device in a broad and diverse range has been suggested.

However, particularly in case of application in a full-color display and the like, for example, it cannot be said that the emission efficiency and durability of a current device are sufficient enough to be put into practical use. Regarding an organic blue-light-emitting device, in particular, as described in SID Symposium Digest, 38, 1504 (2007), the luminance half-life period of is 17,000 hours for initial luminance of 1,000 cd/m² according to the present state of art. As such, an additional improvement in performance has been needed.

In relation to an improvement in stability of a blue-light-emitting device, various materials have been suggested. For example, in Japanese Patent Application Laid-Open No. 2007-318063, a material having a pyrene skeleton and a light-emitting dopant having a fluoranthene skeleton are disclosed. Such materials are all included in an emission layer. Specifically, a material having a pyrene skeleton has an excellent electron transporting property and a light emitting dopant having a fluoranthene skeleton can function as an electron trap.

Furthermore, regarding an organic light-emitting device which includes a material having a pyrene skeleton, WO2005/115950 or WO2005/123634 can be mentioned.

### DISCLOSURE OF INVENTION

### Problems to be Solved by the Invention

It is, therefore, an object of the present invention to provide an organic blue-light-emitting device having high emission efficiency and a long continuous driving lifetime.

### Means for Solving the Problems

The present inventors have made extensive studies to solve the above-described problems. As a result, they accomplished the present invention.

The organic light-emitting device of the present invention includes an anode, a cathode, and a stacked body which is interposed between the anode and the cathode and includes at least a layer which forms a light-emitting region, and the layer which forms the light-emitting region includes at least one of each of (a) and (b) described below:

(a) a first organic compound represented by the following general formula [1] or general formula [2]:

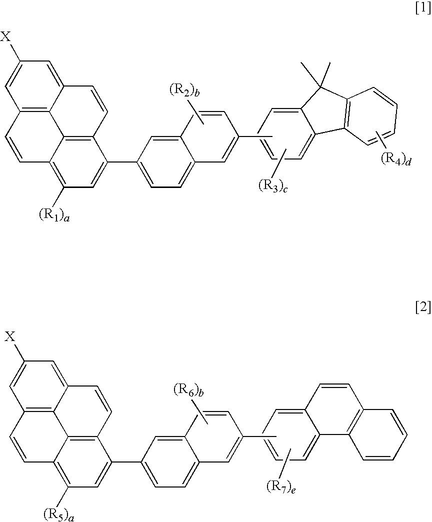

In the general formula [1], R₁ is a substituted or unsubstituted alkyl group. R₂ is a substituted or unsubstituted alkyl group, a substituted or unsubstituted aralkyl group, a substituted or unsubstituted phenyl group or a substituted or unsubstituted aromatic group in which two rings are fused. Each of R₃ and R₄ is a halogen atom, a substituted or unsubstituted alkyl group, a substituted or unsubstituted aralkyl group, a substituted or unsubstituted phenyl group, a substituted or unsubstituted aromatic group wherein two rings are fused, or a substituted or unsubstituted heterocyclic group. a is an integer of 0 to 6. When a is 2 or more, plural R₁'s may be the same or different from each other. d is an integer of 0 to 4. When d is 2 or more, plural R₄'s may be the same or different from each other. b is an integer of 0 to 3. When b is 2 or 3, plural R₂'s may be the same or different from each other. c is an integer of 0 to 3. When c is 2 or 3, plural R₃'s may be the same or different from each other. X is a substituent represented by the following general formula [A]:

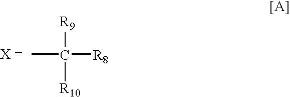

In the general formula [A], at least two of R₈, R₉ and R₁₀ are a substituted or unsubstituted alkyl group while the other substituents are a hydrogen atom. Each of R₈, R₉ and R₁₀ may be the same or different from each other.

In the general formula [2], R₅ is a substituted or unsubstituted alkyl group. R₆ is a substituted or unsubstituted alkyl group, a substituted or unsubstituted aralkyl group, a substituted or unsubstituted phenyl group or a substituted or unsubstituted aromatic group wherein two rings are fused. R₇ is a halogen atom, a substituted or unsubstituted alkyl group, a substituted or unsubstituted aralkyl group, a substituted or unsubstituted phenyl group, a substituted or unsubstituted aromatic group wherein two rings are fused, or a substituted or unsubstituted heterocyclic group. a is an integer of 0 to 6. When a is 2 or more, plural R₅'s may be the same or different from each other. b is an integer of 0 to 3. When b is 2 or 3, plural R₆'s may be the same or different from each other. e is an integer of 0 to 9. When e is 2 or more, plural R₇'s may be the same or different from each other. X is a substituent represented the general formula [A];

(b) a second organic compound represented by the following general formula [3] or general formula [4]

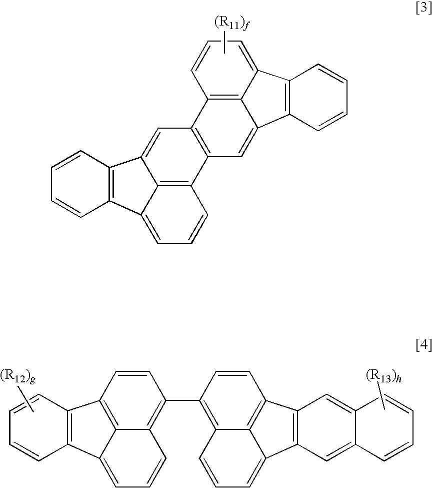

In the general formula [3], R₁₁ is a halogen atom, a substituted or unsubstituted alkyl group, a substituted or unsubstituted aralkyl group, a substituted or unsubstituted aryl group or a substituted or unsubstituted heterocyclic group. f is an integer of 0 to 16. When f is 2 or more, plural R₁₁'s may be the same or different from each other. In the general formula [4], R₁₂ is a substituted or unsubstituted alkyl group, a substituted or unsubstituted aralkyl group, or a substituted or unsubstituted heterocyclic group. R₁₃ is a halogen atom, a substituted or unsubstituted alkyl group, a substituted or unsubstituted aralkyl group, a substituted or unsubstituted phenyl group, a substituted or unsubstituted aromatic group wherein two rings are fused, or a substituted or unsubstituted heterocyclic group. g is an integer of 0 to 9. When g is 2 or more, plural R₁₂'s may be the same or different from each other. h is an integer of 0 to 11. When h is 2 or more, plural R₁₃'s may be the same or different from each other.).

### EFFECT OF THE INVENTION

According to the present invention, an organic blue-light-emitting device having a high emission efficiency and a long continuous driving lifetime can be provided.

### BRIEF DESCRIPTION OF THE DRAWINGS

FIG. 1 is a cross-sectional view showing a first embodiment of an organic light-emitting device in accordance with the present invention.

FIG. 2 is a cross-sectional view showing a second embodiment of an organic light-emitting device in accordance with the present invention.

FIG. 3 is a cross-sectional view showing a third embodiment of an organic light-emitting device in accordance with the present invention.

FIG. 4 is a cross-sectional view showing a fourth embodiment of an organic light-emitting device in accordance with the present invention.

FIG. 5 is a ¹H-NMR (CDCl₃) spectrum of Exemplified Compound D1.

### EXPLANATION OF REFERENCE NUMERALS

1: Substrate
2: Anode
3: Hole-transporting layer
4: Electron-transporting layer
5: Cathode
6: Emission layer
7: Hole injection layer
8: Hole-blocking layer
10, 20, 30, and 40: Organic light-emitting device

### BEST MODE FOR CARRYING OUT THE INVENTION

The organic light-emitting device of the present invention includes an anode, a cathode, and a stacked body which is interposed between the anode and the cathode and includes at least a layer which forms a light-emitting region. Hereinafter, the organic light-emitting device in accordance with the present invention will be explained in detail with reference to the accompanying drawings.

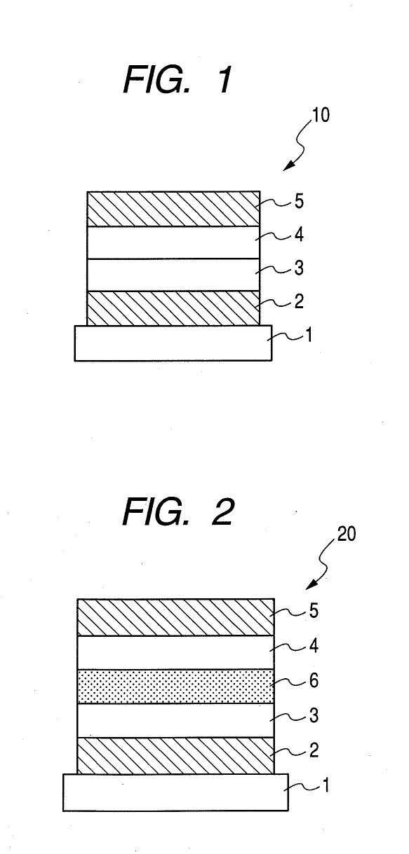

FIG. 1 is a cross-sectional view showing a first embodiment of an organic light-emitting device in accordance with the present invention. An organic light-emitting device 10 of FIG. 1 is obtained by sequentially providing, on a substrate 1, an anode 2, a hole-transporting layer 3, an electron-transporting layer 4, and a cathode 5. In the organic light-emitting device 10 of FIG. 1, one of the hole-transporting layer 3 and the electron-transporting layer 4 also serves as an emission layer.

FIG. 2 is a cross-sectional view showing a second embodiment of the organic light-emitting device in accordance with the present invention. An organic light-emitting device 20 of FIG. 2 is obtained by further providing an emission layer 6 between the hole-transporting layer 3 and the electron-transporting layer 4 of the organic light-emitting device 10 of FIG. 1. In the organic light-emitting device 20 of FIG. 2, a carrier transport function and a light-emitting function are separated from each other, and a region in which holes and electrons are recombined with each other is present in the emission layer 6. Furthermore, for the organic light-emitting device 20 of FIG. 2, compounds having respective properties such as a hole transporting property, an electron transporting property, and a light-emitting property can be used in an appropriate combination so that the degree of freedom in the selection of materials can be increased significantly. In addition, the variety of emission hues can be obtained because various compounds having different emission wavelengths can be used. Furthermore, emission efficiency can be improved by effectively confining respective carriers or excitons in the emission layer 6 located in a central region.

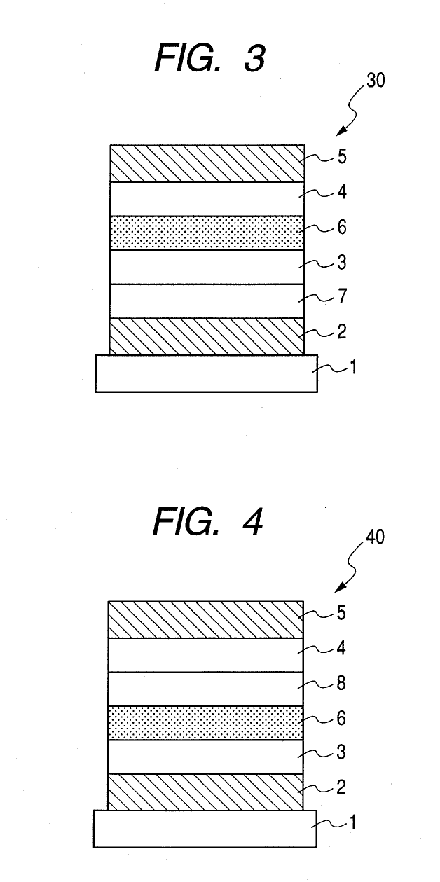

FIG. 3 is a cross-sectional view showing a third embodiment of the organic light-emitting device in accordance with the present invention. An organic light-emitting device 30 of FIG. 3 includes a hole injection layer 7 as one kind of a hole-transporting layer formed between the anode 2 and the hole-transporting layer 3 of the organic light-emitting device 20 of FIG. 2. Since the organic light-emitting device 30 of FIG. 3 has an improving effect on adhesiveness between the anode 2 and the hole-transporting layer 5 or on a hole injection property, it is useful for reducing a voltage that is required to drive a device.

FIG. 4 is a cross-sectional view showing a fourth embodiment of the organic light-emitting device in accordance with the present invention. An organic light-emitting device 40 of FIG. 4 includes a hole-blocking layer 8 as one kind of an electron-transporting layer formed between the emission layer 6 and the electron-transporting layer 4 of the organic light-emitting device 20 of FIG. 2. By employing a compound with a large ionization potential (i.e., having a low HOMO energy) as a constitutional material for the hole-blocking layer 8, the leak of holes from the emission layer 6 toward the cathode 5 side is suppressed so that it is effective for increasing the emission efficiency of the device.

However, the constitution of the organic light-emitting device in accordance with the present invention is not limited to those described in the above. For example, it is also possible that an electron-blocking layer or an election injection layer can be further provided as an intermediate layer. In addition, two or more emission layers can be provided. When two or more emission layers are provided, each of the emission layers can be formed adjacently or separated from each other.

The organic light-emitting device in accordance with the present invention includes at least one of each of organic compounds (a) and (b) described below in a layer which forms a light-emitting region.

(a) a first organic compound represented by the following general formula [1] or general formula [2]:

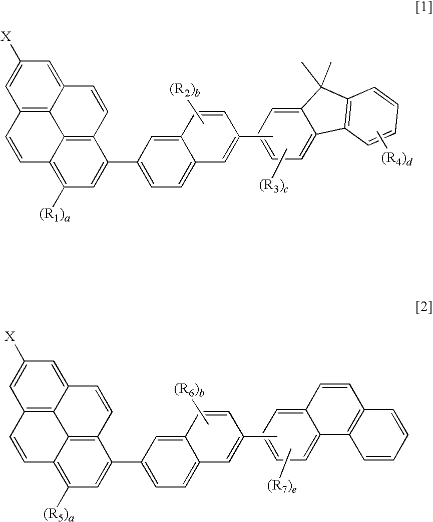

and

(b) a second organic compound represented by the following general formula [3] or general formula [4]:

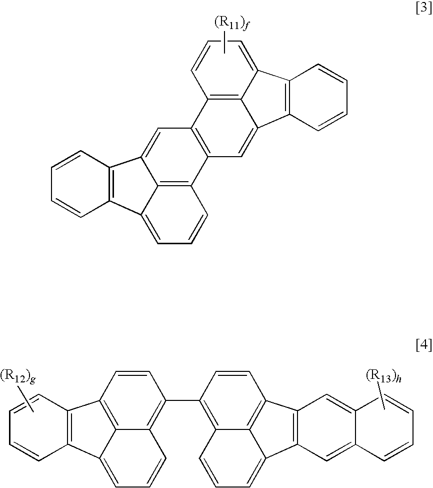

Incidentally, detailed descriptions about the compounds that are represented by the general formulae [1] to [4] will be given below. Furthermore, each of the first organic compound and the second organic compound that are included in a layer which forms a light-emitting region may be either a single kind or two or more kinds, respectively.

In the present context, the term “a layer which forms a light-emitting region” herein employed refers to any one of the hole-transporting layer 3 and the electron-transporting layer 4 in the case of the organic light-emitting device 10 shown in FIG. 1. However, in the organic light-emitting device 10 of FIG. 1, the light-emitting region may include an interface between the hole-transporting layer 3 and the electron-transporting layer 4.

Meanwhile, in the organic light-emitting devices 20, 30, 40 shown in FIGS. 2 to 4, at least the emission layer 5 corresponds to the light-emitting region. In addition, in the case where there are two or more layers which form a light-emitting region, any of such layers may include the above-described first organic compound (a) and the second organic compound (b). In addition, in the organic light-emitting devices 20, 30, 40 shown in FIGS. 2 to 4, the light-emitting region may include not only a layer which forms a light-emitting region but also an interface between the layer which forms a light-emitting region and the layer which is located adjacent to the layer which forms a light-emitting region.

Next, the first organic compound and the second organic compound that are included in a layer which forms a light-emitting region will be explained. First, explanations are given for the first organic compound.

The first organic compound that is included in a layer which forms a light-emitting region is a compound which functions as a host in the layer which forms a light-emitting region. In addition, the pyrene compound as the first organic compound has at least a pyrene skeleton and a naphthalene skeleton. Specifically, it corresponds to a compound that is represented by the following general formula [1] or general formula [2]:

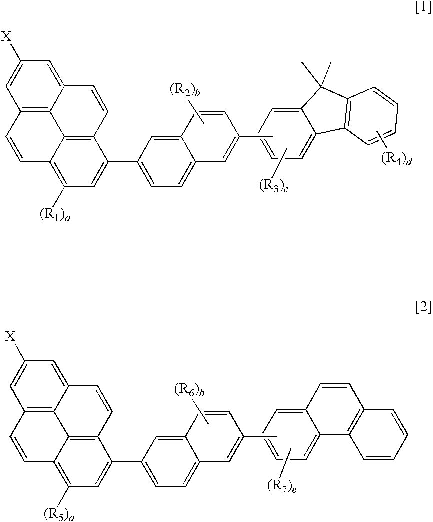

First, the compound of the general formula [1] will be explained.

In the general formula [1], R₁ represents a substituted or unsubstituted alkyl group.

With respect to a substituted or unsubstituted alkyl group as R₁, examples include, but are not limited to, methyl group, methyl-d₁ group, methyl-d₃ group, ethyl group, ethyl-d₅ group, n-propyl group, n-butyl group, n-pentyl group, n-hexyl group, n-heptyl group, n-octyl group, n-decyl group, iso-propyl group, iso-propyl-d₇ group, iso-butyl group, sec-butyl group, tert-butyl group, tert-butyl-d₉ group, iso-pentyl group, neopentyl group, tert-octyl group, fluoromethyl group, difluoromethyl group, trifluoromethyl group, 2-fluoroethyl group, 2,2,2-trifluoroethyl group, perfluoroethyl group, 3-fluoropropyl group, perfluoropropyl group, 4-fluorobutyl group, perfluorobutyl group, 5-fluoropentyl group, 6-fluorohexyl group, chloromethyl group, trichloromethyl group, 2-chloroethyl group, 2,2,2-trichloroethyl group, 4-chlorobutyl group, 5-chloropentyl group, 6-chlorohexyl group, bromomethyl group, 2-bromoethyl group, iodomethyl group, 2-iodoethyl group, hydroxymethyl group, hydroxyethyl group, cyclopropyl group, cyclobutyl group, cyclopentyl group, cyclohexyl group, cyclopentylmethyl group, cyclohexylmethyl group, cyclohexylethyl group, 4-fluorocyclohexyl group, norbornyl group, and adamantyl group.

In the general formula [1], R₂ represents a substituted or unsubstituted alkyl group, a substituted or unsubstituted aralkyl group, a substituted or unsubstituted phenyl group or an aromatic group in which two substituted or unsubstituted rings are fused.

With respect to a substituted or unsubstituted alkyl group as R₂, examples include, but are not limited to, methyl group, methyl-d₁ group, methyl-d₃ group, ethyl group, ethyl-d₅ group, n-propyl group, n-butyl group, n-pentyl group, n-hexyl group, n-heptyl group, n-octyl group, n-decyl group, iso-propyl group, iso-propyl-d₇ group, iso-butyl group, sec-butyl group, tert-butyl group, tert-butyl-d₉ group, iso-pentyl group, neopentyl group, tert-octyl group, fluoromethyl group, difluoromethyl group, trifluoromethyl group, 2-fluoroethyl group, 2,2,2-trifluoroethyl group, perfluoroethyl group, 3-fluoropropyl group, perfluoropropyl group, 4-fluorobutyl group, perfluorobutyl group, 5-fluoropentyl group, 6-fluorohexyl group, chloromethyl group, trichloromethyl group, 2-chloroethyl group, 2,2,2-trichloroethyl group, 4-chlorobutyl group, 5-chloropentyl group, 6-chlorohexyl group, bromomethyl group, 2-bromoethyl group, iodomethyl group, 2-iodoethyl group, hydroxymethyl group, hydroxyethyl group, cyclopropyl group, cyclobutyl group, cyclopentyl group, cyclohexyl group, cyclopentylmethyl group, cyclohexylmethyl group, cyclohexylethyl group, 4-fluorocyclohexyl group, norbornyl group, and adamantyl group.

With respect to a substituted or unsubstituted aralkyl group as R₂, examples include, but are not limited to, benzyl group, 2-phenylethyl group, 2-phenylisopropyl group, 1-naphthylmethyl group, 2-naphthylmethyl group, 2-(1-naphthyl)ethyl group, 2-(2-naphthyl)ethyl group, 9-anthrylmethyl group, 2-(9-anthryl)ethyl group, 2-fluorobenzyl group, 3-fluorobenzyl group, 4-fluorobenzyl group, 2-chlorobenzyl group, 3-chlorobenzyl group, 4-chlorobenzyl group, 2-bromobenzyl group, 3-bromobenzyl group, and 4-bromobenzyl group.

With respect to a substituted or unsubstituted phenyl group as R₂, examples include, but are not limited to, phenyl group, phenyl-d₅ group, 2-methylphenyl group, 3-methylphenyl group, 4-methylphenyl group, 4-methoxyphenyl group, 4-ethylphenyl group, 2-fluorophenyl group, 3-fluorophenyl group, 4-fluorophenyl group, 4-trifluoromethylphenyl group, 3,5-dimethylphenyl group, 2,6-dimethylphenyl group, 2,6-diethylphenyl group, mesityl group, 3-iso-propylphenyl group, 3-tert-butylphenyl group, 4-iso-propylphenyl group, 4-tert-butylphenyl group, 4-cyanophenyl group, 4-(di-p-tolylamino)phenyl group, biphenyl group, and terphenyl group.

With respect to an aromatic group as R₂ in which two rings are fused, examples include, but are not limited to, naphthyl group, azulene group, and heptalene group. In addition, the aromatic group as R₂ in which two rings are fused may include an additional substituent group, and examples thereof include, but are not limited to, an alkyl group such as methyl group, ethyl group, propyl group and tert-butyl, an aryl group such as phenyl group and biphenyl group, a heterocyclic group such as thienyl group, pyrrollyl group and pyridyl group, a substituted amino group such as dimethylamino group, diethylamino group, dibenzylamino group, diphenylamino group, ditolylamino group and dianisolylamino group, an alkoxy group such as methoxy group, ethoxy group, propoxy group, 2-ethyl-octyloxy group and benzyloxy group, an aryloxy group such as phenoxy group, 4-tert-butylphenoxy group and thienyloxy group, a halogen atom such as fluorine, chlorine, bromine and iodine, hydroxy group, cyano group, and nitro group.

In the general formula [1], R₃ and R₄ respectively represent a halogen atom, a substituted or unsubstituted alkyl group, a substituted or unsubstituted aralkyl group, a substituted or unsubstituted phenyl group, a substituted or unsubstituted aromatic group in which two rings are fused, or a substituted or unsubstituted heterocyclic group.

As a halogen atom as R₃ or R₄, fluorine, chlorine, bromine or iodine can be mentioned.

With respect to a substituted or unsubstituted alkyl group as R₃ or R₄, examples include, but are not limited to, methyl group, methyl-d₁ group, methyl-d₃ group, ethyl group, ethyl-d₅ group, n-propyl group, n-butyl group, n-pentyl group, n-hexyl group, n-heptyl group, n-octyl group, n-decyl group, iso-propyl group, iso-propyl-d₇ group, iso-butyl group, sec-butyl group, tert-butyl group, tert-butyl-d₉ group, iso-pentyl group, neopentyl group, tert-octyl group, fluoromethyl group, difluoromethyl group, trifluoromethyl group, 2-fluoroethyl group, 2,2,2-trifluoroethyl group, perfluoroethyl group, 3-fluoropropyl group, perfluoropropyl group, 4-fluorobutyl group, perfluorobutyl group, 5-fluoropentyl group, 6-fluorohexyl group, chloromethyl group, trichloromethyl group, 2-chloroethyl group, 2,2,2-trichloroethyl group, 4-chlorobutyl group, 5-chloropentyl group, 6-chlorohexyl group, bromomethyl group, 2-bromoethyl group, iodomethyl group, 2-iodoethyl group, hydroxymethyl group, hydroxyethyl group, cyclopropyl group, cyclobutyl group, cyclopentyl group, cyclohexyl group, cyclopentylmethyl group, cyclohexylmethyl group, cyclohexylethyl group, 4-fluorocyclohexyl group, norbornyl group, and adamantyl group.

With respect to a substituted or unsubstituted aralkyl group as R₃ or R₄, examples include, but are not limited to, benzyl group, 2-phenylethyl group, 2-phenylisopropyl group, 1-naphthylmethyl group, 2-naphthylmethyl group, 2-(1-naphthyl)ethyl group, 2-(2-naphthyl)ethyl group, 9-anthrylmethyl group, 2-(9-anthryl)ethyl group, 2-fluorobenzyl group, 3-fluorobenzyl group, 4-fluorobenzyl group, 2-chlorobenzyl group, 3-chlorobenzyl group, 4-chlorobenzyl group, 2-bromobenzyl group, 3-bromobenzyl group, and 4-bromobenzyl group.

With respect to a substituted or unsubstituted phenyl group as R₃ or R₄, examples include, but are not limited to, phenyl group, phenyl-d₅ group, 2-methylphenyl group, 3-methylphenyl group, 4-methylphenyl group, 4-methoxyphenyl group, 4-ethylphenyl group, 2-fluorophenyl group, 3-fluorophenyl group, 4-fluorophenyl group, 4-trifluoromethylphenyl group, 3,5-dimethylphenyl group, 2,6-dimethylphenyl group, 2,6-diethylphenyl group, mesityl group, 3-iso-propylphenyl group, 3-tert-butylphenyl group, 4-iso-propylphenyl group, 4-tert-butylphenyl group, 4-cyanophenyl group, 4-(di-p-tolylamino)phenyl group, biphenyl group, and terphenyl group.

With respect to an aromatic group as R₃ or R₄ in which two rings are fused, examples include, but are not limited to, naphthyl group, azulene group, and heptalene group.

With respect to a heterocyclic group as R₃ or R₄, examples include, but are not limited to, pyrrollyl group, pyridyl group, pyridyl-d₅ group, bipyridyl group, methylpyridyl group, pyrimidinyl group, pyrazinyl group, pyridazinyl group, terpyrrollyl group, thienyl group, thienyl-d₄ group, terthienyl group, propylthienyl group, benzothienyl group, dibenzothienyl group, dibenzothienyl-d₇ group, furyl group, furyl-d₄ group, benzofuryl group, isobenzofuryl group, dibenzofuryl group, dibenzofuryl-d₇ group, quinolyl group, quinolyl-d₆ group, isoquinolyl group, quinoxalinyl group, naphthylidinyl group, quinazolinyl group, phenanthridinyl group, indolidinyl group, phenadinyl group, carbazolyl group, oxazolyl group, oxadiazolyl group, thiazolyl group, thiadiazolyl group, acridinyl group, and phenazinyl group.

The aromatic group in which two rings are fused and the heterocyclic group may include an additional substituent group, and examples thereof include, but are not limited to, an alkyl group such as methyl group, ethyl group, propyl group and tert-butyl group, an aryl group such as phenyl group and biphenyl group, a heterocyclic group such as thienyl group, pyrrollyl group and pyridyl group, a substituted amino group such as dimethylamino group, diethylamino group, dibenzylamino group, diphenylamino group, ditolylamino group and dianisolylamino group, an alkoxy group such as methoxy group, ethoxy group, propoxy group, 2-ethyl-octyloxy group and benzyloxy group, an aryl oxy group such as phenoxy group, 4-tert-butylphenoxy group and thienyloxy group, a halogen atom such as fluorine, chlorine, bromine and iodine, hydroxy group, cyano group, and nitro group.

In the general formula [1], a is an integer of 0 to 6. When a is 2 or more, plural R₁'s may be the same or different from each other.

In the general formula [1], b is an integer of 0 to 3. When b is 2 or 3, plural R₂'s may be the same or different from each other.

In the general formula [1], c is an integer of 0 to 3. When c is 2 or 3, plural R₃'s may be the same or different from each other.

In the general formula [1], d is an integer of 0 to 4. When d is 2 or more, plural R₄'s may be the same or different from each other.

In the general formula [1], X is a substituent represented by the general formula [A] described below.

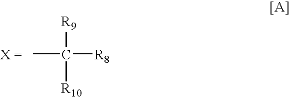

In the general formula [A], at least two of R₈, R₉ and R₁₀ are a substituted or unsubstituted alkyl group, and the remaining substituents are a hydrogen atom. The substituted or unsubstituted alkyl group represented by R₈ to R₁₀ is the same as the substituted or unsubstituted alkyl group represented by R₁ in the general formula [1].

Each of R₈ to R₁₀ may be the same or different from each other.

X in the general formula [1] is preferably iso-propyl group or tert-butyl group, and more preferably tert-butyl group, in terms of the synthesis of a compound. That is, it is preferable that all of R₈ to R₁₀ are methyl group.

Next, the compound of the general formula [2] will be explained.

In the general formula [2], R₅ represents a substituted or unsubstituted alkyl group. Specific examples of the alkyl group as R₅, and a substituent which can be included in the alkyl group are the same as the specific examples of R₁ in the general formula [1].

In the general formula [2], R₆ represents a substituted or unsubstituted alkyl group, a substituted or unsubstituted aralkyl group, a substituted or unsubstituted phenyl group, or a substituted or unsubstituted aromatic group in which two rings are fused. Specific examples of the substituted or unsubstituted alkyl group, the substituted or unsubstituted aralkyl group and the substituted or unsubstituted phenyl group as R₆ are the same as the specific examples of R₂ in the general formula [1]. Furthermore, specific examples of the substituted or unsubstituted aromatic group as R₆ in which two rings are fused and the substituent which can be included in the aromatic group are the same as the specific examples of R₂ in the general formula [1].

In the general formula [2], R₇ represents a halogen atom, a substituted or unsubstituted alkyl group, a substituted or unsubstituted aralkyl group, a substituted or unsubstituted phenyl group, a substituted or unsubstituted aromatic group in which two rings are fused, or a substituted or unsubstituted heterocyclic group. Specific examples of a halogen atom, a substituted or unsubstituted alkyl group, a substituted or unsubstituted aralkyl group, and a substituted or unsubstituted phenyl group as R₇ are the same as the specific examples of R₃ or R₄ in the general formula [1]. Furthermore, specific examples of the substituted or unsubstituted aromatic group in which two rings are fused and the heterocyclic group and a substituent which can be included in the substituted or unsubstituted aromatic group in which two rings are fused and the heterocyclic group are the same as the specific examples of R₃ or R₄ in the general formula [1].

In the general formula [2], a is an integer of 0 to 6. When a is 2 or more, plural R₅'s may be the same or different from each other.

In the general formula [2], b is an integer of 0 to 3. When b is 2 or 3, plural R₆'s may be the same or different from each other.

In the general formula [2], e is an integer of 0 to 9. When e is 2 or more, plural R₇'s may be the same or different from each other.

In the general formula [2], X is a substituent represented by the general formula [A] described below. Specific structure of X is the same as X in the general formula [1].

Hereinafter, specific examples of the first organic compound will be enumerated. However, it is to be noted that the present invention is not limited thereto.

### [Specific Examples of the General Formula [1]]

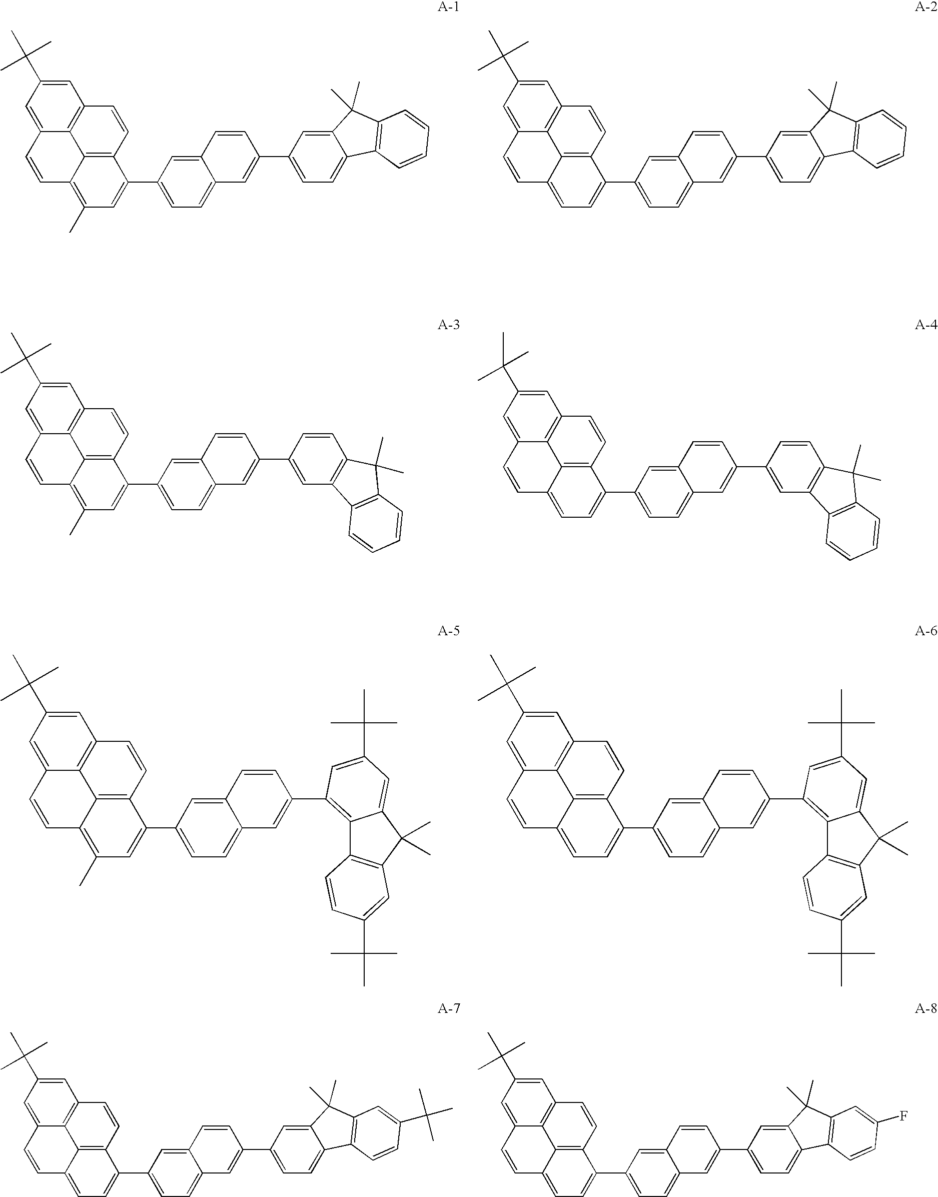

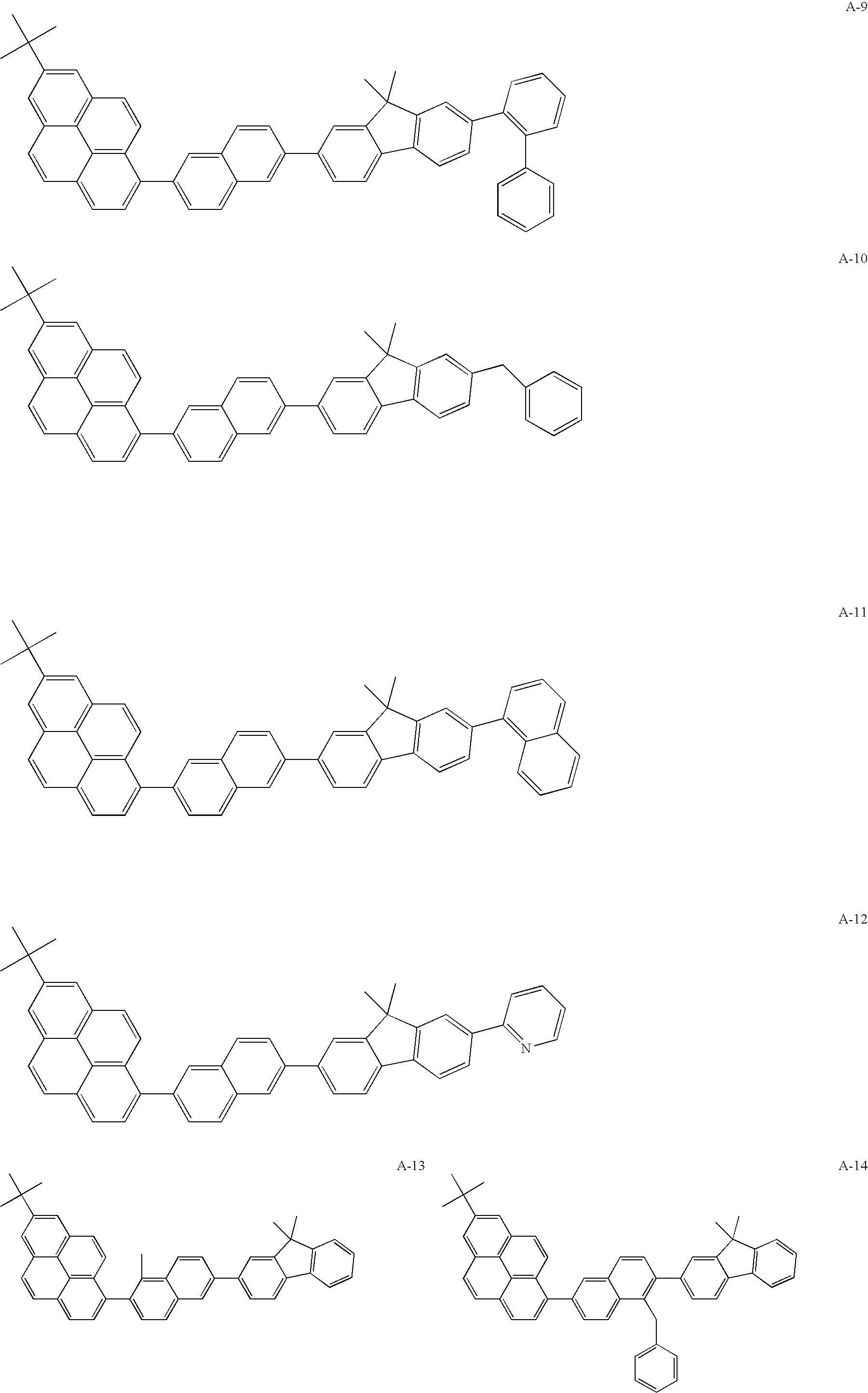

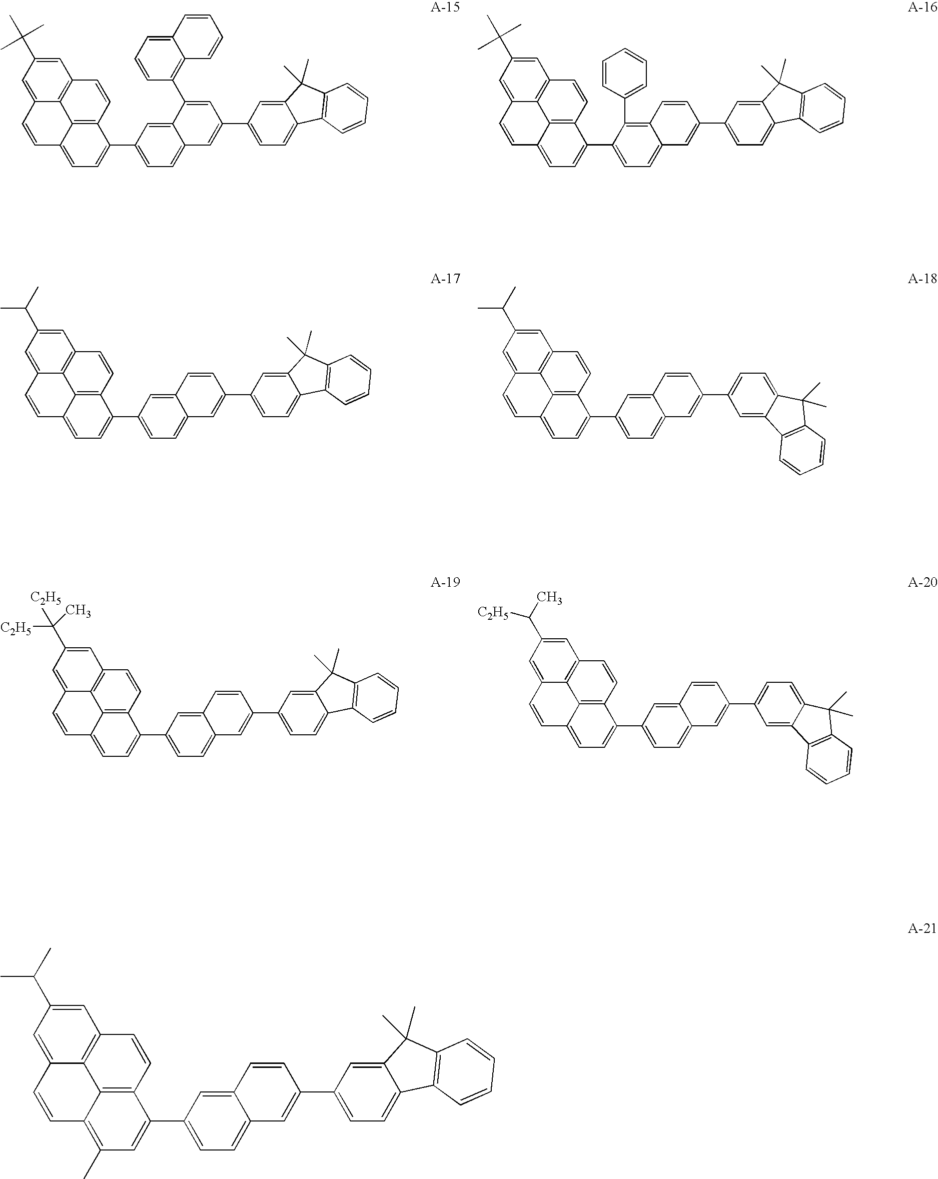

### [Specific Examples of the General Formula [2]]

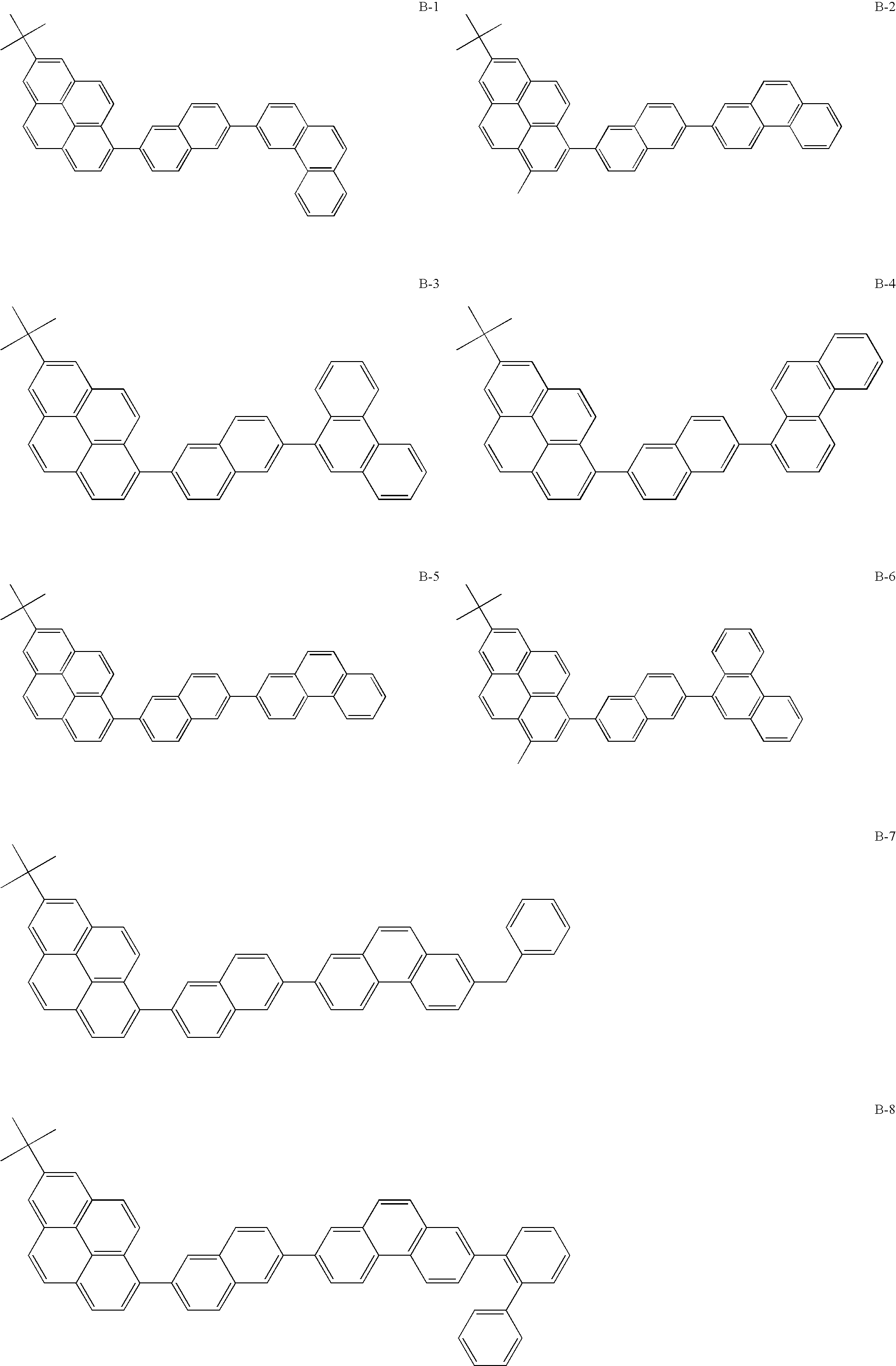

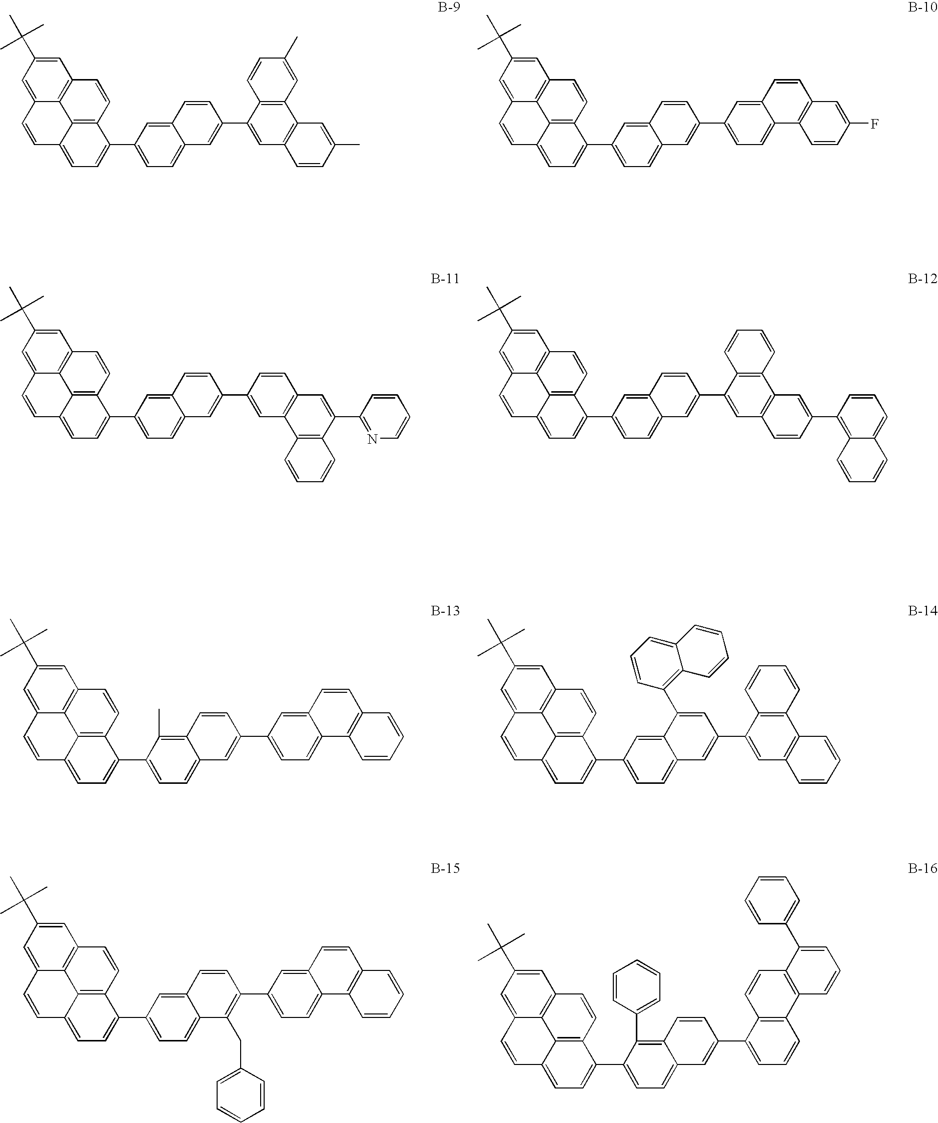

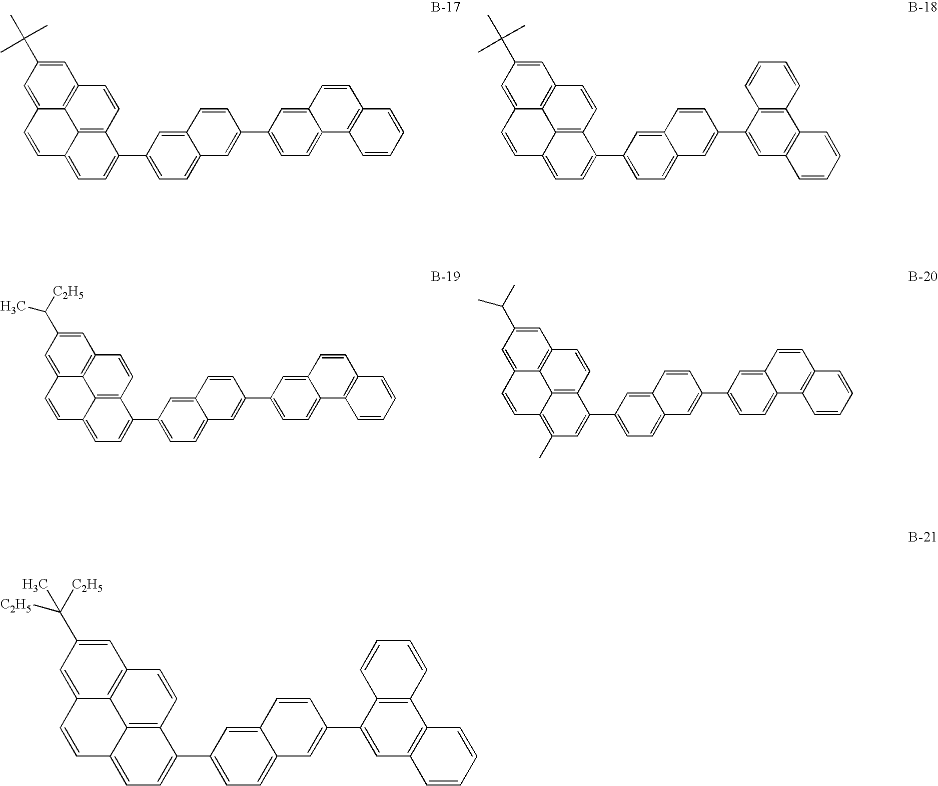

Next, the second organic compound will be explained. The second organic compound which is included in a layer which forms a light-emitting region is a compound that functions as a blue light emitting dopant for the layer which forms a light-emitting region. In addition, a fused ring aromatic compound as the second organic compound specifically indicates the compound represented by the following general formula [3] or general formula [4]:

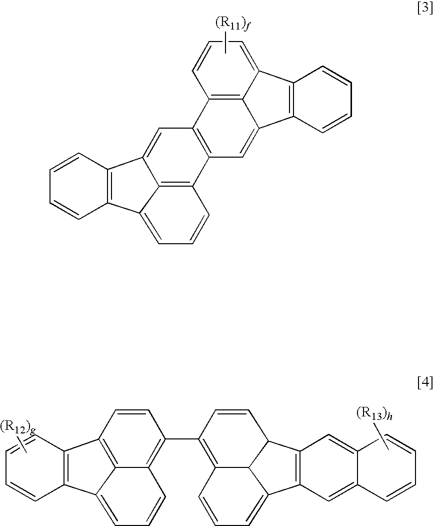

First, the compound of the general formula [3] will be explained.

In the general formula [3], R₁₁ represents a halogen atom, a substituted or unsubstituted alkyl group, a substituted or unsubstituted aralkyl group, a substituted or unsubstituted aryl group, or a substituted or unsubstituted heterocyclic group.

As a halogen atom represented by R₁₁, fluorine, chlorine, bromine or iodine can be mentioned.

With respect to a substituted or unsubstituted alkyl group as R₁₁, examples include, but are not limited to, methyl group, methyl-d₁ group, methyl-d₃ group, ethyl group, ethyl-d₅ group, n-propyl group, n-butyl group, n-pentyl group, n-hexyl group, n-heptyl group, n-octyl group, n-decyl group, iso-propyl group, iso-propyl-d₇ group, iso-butyl group, sec-butyl group, tert-butyl group, tert-butyl-d₉ group, iso-pentyl group, neopentyl group, tert-octyl group, fluoromethyl group, difluoromethyl group, trifluoromethyl group, 2-fluoroethyl group, 2,2,2-trifluoroethyl group, perfluoroethyl group, 3-fluoropropyl group, perfluoropropyl group, 4-fluorobutyl group, perfluorobutyl group, 5-fluoropentyl group, 6-fluorohexyl group, chloromethyl group, trichloromethyl group, 2-chloroethyl group, 2,2,2-trichloroethyl group, 4-chlorobutyl group, 5-chloropentyl group, 6-chlorohexyl group, bromomethyl group, 2-bromoethyl group, iodomethyl group, 2-iodoethyl group, hydroxymethyl group, hydroxyethyl group, cyclopropyl group, cyclobutyl group, cyclopentyl group, cyclohexyl group, cyclopentylmethyl group, cyclohexylmethyl group, cyclohexylethyl group, 4-fluorocyclohexyl group, norbornyl group, and adamantyl group.

With respect to a substituted or unsubstituted aralkyl group as R₁₁, examples include, but are not limited to, benzyl group, 2-phenylethyl group, 2-phenylisopropyl group, 1-naphthylmethyl group, 2-naphthylmethyl group, 2-(1-naphthyl)ethyl group, 2-(2-naphthyl)ethyl group, 9-anthrylmethyl group, 2-(9-anthryl)ethyl group, 2-fluorobenzyl group, 3-fluorobenzyl group, 4-fluorobenzyl group, 2-chlorobenzyl group, 3-chlorobenzyl group, 4-chlorobenzyl group, 2-bromobenzyl group, 3-bromobenzyl group, and 4-bromobenzyl group.

With respect to an aryl group as R₁₁, examples include phenyl group, naphthyl group, pentarenyl group, indenyl group, azulenyl group, anthryl group, pyrenyl group, indazenyl group, acenaphthenyl group, phenanthryl group, phenalenyl group, fluoranthenyl group, acephenanthryl group, aceanthryl group, triphenylenyl group, chrysenyl group, naphthacenyl group, perylenyl group, pentacenyl group, biphenyl group, terphenyl group, and fluorenyl group.

With respect to a heterocyclic group as R₁₁, examples include, but are not limited to, pyrrollyl group, pyridyl group, pyridyl-d₅ group, bipyridyl group, methylpyridyl group, pyrimidinyl group, pyrazinyl group, pyridazinyl group, terpyrrollyl group, thienyl group, thienyl-d₄ group, terthienyl group, propylthienyl group, benzothienyl group, dibenzothienyl group, dibenzothienyl-d₇ group, furyl group, furyl-d₄ group, benzofuryl group, isobenzofuryl group, dibenzofuryl group, dibenzofuryl-d₇ group, quinolyl group, quinolyl-d₆ group, isoquinolyl group, quinoxalinyl group, naphthylidinyl group, quinazolinyl group, phenanthridinyl group, indolidinyl group, phenadinyl group, carbazolyl group, oxazolyl group, oxadiazolyl group, thiazolyl group, thiadiazolyl group, acridinyl group, and phenazinyl group.

The above-described aryl group and the heterocyclic group may include an additional substituent group, and examples thereof include, but are not limited to, an alkyl group such as methyl group, ethyl group, propyl group and tert-butyl, an aryl group such as phenyl group and biphenyl group, a heterocyclic group such as thienyl group, pyrrollyl group and pyridyl group, a substituted amino group such as dimethylamino group, diethylamino group, dibenzylamino group, diphenylamino group, ditolylamino group and dianisolylamino group, an alkoxy group such as methoxy group, ethoxy group, propoxy group, 2-ethyl-octyloxy group and benzyloxy group, an aryloxy group such as phenoxy group, 4-tert-butylphenoxy group and thienyloxy group, a halogen atom such as fluorine, chlorine, bromine and iodine, hydroxy group, cyano group, and nitro group.

In the general formula [3], f represents an integer of 0 to 16. When f is 2 or more, plural R₁₁'s may be the same or different from each other.

Next, the compound of the general formula [4] will be explained.

In the General formula [4], R₁₂ represents a substituted or unsubstituted alkyl group, a substituted or unsubstituted aralkyl group, or a substituted or unsubstituted heterocyclic group.

With respect to a substituted or unsubstituted alkyl group as R₁₂, examples include, but are not limited to, methyl group, methyl-d₁ group, methyl-d₃ group, ethyl group, ethyl-d₅ group, n-propyl group, n-butyl group, n-pentyl group, n-hexyl group, n-heptyl group, n-octyl group, n-decyl group, iso-propyl group, iso-propyl-d₇ group, iso-butyl group, sec-butyl group, tert-butyl group, tert-butyl-d₉ group, iso-pentyl group, neopentyl group, tert-octyl group, fluoromethyl group, difluoromethyl group, trifluoromethyl group, 2-fluoroethyl group, 2,2,2-trifluoroethyl group, perfluoroethyl group, 3-fluoropropyl group, perfluoropropyl group, 4-fluorobutyl group, perfluorobutyl group, 5-fluoropentyl group, 6-fluorohexyl group, chloromethyl group, trichloromethyl group, 2-chloroethyl group, 2,2,2-trichloroethyl group, 4-chlorobutyl group, 5-chloropentyl group, 6-chlorohexyl group, bromomethyl group, 2-bromoethyl group, iodomethyl group, 2-iodoethyl group, hydroxymethyl group, hydroxyethyl group, cyclopropyl group, cyclobutyl group, cyclopentyl group, cyclohexyl group, cyclopentylmethyl group, cyclohexylmethyl group, cyclohexylethyl group, 4-fluorocyclohexyl group, norbornyl group, and adamantyl group.

With respect to a substituted or unsubstituted aralkyl group as R₁₂, examples include, but are not limited to, benzyl group, 2-phenylethyl group, 2-phenylisopropyl group, 1-naphthylmethyl group, 2-naphthylmethyl group, 2-(1-naphthyl)ethyl group, 2-(2-naphthyl)ethyl group, 9-anthrylmethyl group, 2-(9-anthryl)ethyl group, 2-fluorobenzyl group, 3-fluorobenzyl group, 4-fluorobenzyl group, 2-chlorobenzyl group, 3-chlorobenzyl group, 4-chlorobenzyl group, 2-bromobenzyl group, 3-bromobenzyl group, and 4-bromobenzyl group.

With respect to a heterocyclic group as R₁₂, examples include, but are not limited to, pyrrollyl group, pyridyl group, pyridyl-d₅ group, bipyridyl group, methylpyridyl group, pyrimidinyl group, pyrazinyl group, pyridazinyl group, terpyrrollyl group, thienyl group, thienyl-d₄ group, terthienyl group, propylthienyl group, benzothienyl group, dibenzothienyl group, dibenzothienyl-d₇ group, furyl group, furyl-d₄ group, benzofuryl group, isobenzofuryl group, dibenzofuryl group, dibenzofuryl-d₇ group, quinolyl group, quinolyl-d₆ group, isoquinolyl group, quinoxalinyl group, naphthylidinyl group, quinazolinyl group, phenanthridinyl group, indolidinyl group, phenadinyl group, carbazolyl group, oxazolyl group, oxadiazolyl group, thiazolyl group, thiadiazolyl group, acridinyl group, and phenazinyl group.

The above-described heterocyclic group may include an additional substituent group, and examples thereof include, but are not limited to, an alkyl group such as methyl group, ethyl group, propyl group and tert-butyl group, an aryl group such as phenyl group and biphenyl group, a heterocyclic group such as thienyl group, pyrrollyl group and pyridyl group, a substituted amino group such as dimethylamino group, diethylamino group, dibenzylamino group, diphenylamino group, ditolylamino group and dianisolylamino group, an alkoxy group such as methoxy group, ethoxy group, propoxy group, 2-ethyl-octyloxy group and benzyloxy group, an aryloxy group such as phenoxy group, 4-tert-butylphenoxy group and thienyloxy group, a halogen atom such as fluorine, chlorine, bromine and iodine, hydroxy group, cyano group, and nitro group.

In the general formula [4], R₁₃ represents a halogen atom, a substituted or unsubstituted alkyl group, a substituted or unsubstituted aralkyl group, a substituted or unsubstituted phenyl group, a substituted or unsubstituted aromatic group in which two rings are fused, or a substituted or unsubstituted heterocyclic group.

As a halogen atom represented by R₁₃, fluorine, chlorine, bromine or iodine can be mentioned.

With respect to a substituted or unsubstituted alkyl group as R₁₃, examples include, but are not limited to, methyl group, methyl-d₁ group, methyl-d₃ group, ethyl group, ethyl-d₅ group, n-propyl group, n-butyl group, n-pentyl group, n-hexyl group, n-heptyl group, n-octyl group, n-decyl group, iso-propyl group, iso-propyl-d₇ group, iso-butyl group, sec-butyl group, tert-butyl group, tert-butyl-d₉ group, iso-pentyl group, neopentyl group, tert-octyl group, fluoromethyl group, difluoromethyl group, trifluoromethyl group, 2-fluoroethyl group, 2,2,2-trifluoroethyl group, perfluoroethyl group, 3-fluoropropyl group, perfluoropropyl group, 4-fluorobutyl group, perfluorobutyl group, 5-fluoropentyl group, 6-fluorohexyl group, chloromethyl group, trichloromethyl group, 2-chloroethyl group, 2,2,2-trichloroethyl group, 4-chlorobutyl group, 5-chloropentyl group, 6-chlorohexyl group, bromomethyl group, 2-bromoethyl group, iodomethyl group, 2-iodoethyl group, hydroxymethyl group, hydroxyethyl group, cyclopropyl group, cyclobutyl group, cyclopentyl group, cyclohexyl group, cyclopentylmethyl group, cyclohexylmethyl group, cyclohexylethyl group, 4-fluorocyclohexyl group, norbornyl group, and adamantyl group.

With respect to a substituted or unsubstituted aralkyl group as R₁₃, examples include, but are not limited to, benzyl group, 2-phenylethyl group, 2-phenylisopropyl group, 1-naphthylmethyl group, 2-naphthylmethyl group, 2-(1-naphthyl)ethyl group, 2-(2-naphthyl)ethyl group, 9-anthrylmethyl group, 2-(9-anthryl)ethyl group, 2-fluorobenzyl group, 3-fluorobenzyl group, 4-fluorobenzyl group, 2-chlorobenzyl group, 3-chlorobenzyl group, 4-chlorobenzyl group, 2-bromobenzyl group, 3-bromobenzyl group, and 4-bromobenzyl group.

With respect to a substituted or unsubstituted phenyl group as R₁₃, examples include, but are not limited to, phenyl group, phenyl-d₅ group, 2-methylphenyl group, 3-methylphenyl group, 4-methylphenyl group, 4-methoxyphenyl group, 4-ethylphenyl group, 2-fluorophenyl group, 3-fluorophenyl group, 4-fluorophenyl group, 4-trifluoromethylphenyl group, 3,5-dimethylphenyl group, 2,6-dimethylphenyl group, 2,6-diethylphenyl group, mesityl group, 3-iso-propylphenyl group, 3-tert-butylphenyl group, 4-iso-propylphenyl group, 4-tert-butylphenyl group, 4-cyanophenyl group, 4-(di-p-tolylamino)phenyl group, biphenyl group, terphenyl group, and 3-(2-pyridyl)phenyl group.

With respect to an aromatic group as R₁₃ in which two rings are fused, examples include, but are not limited to, naphthyl group, azulene group, and heptalene group.

With respect to a heterocyclic group as R₁₃, examples include, but are not limited to, pyrrollyl group, pyridyl group, pyridyl-d₅ group, bipyridyl group, methylpyridyl group, pyrimidinyl group, pyrazinyl group, pyridazinyl group, terpyrrollyl group, thienyl group, thienyl-d₄ group, terthienyl group, propylthienyl group, benzothienyl group, dibenzothienyl group, dibenzothienyl-d₇ group, furyl group, furyl-d₄ group, benzofuryl group, isobenzofuryl group, dibenzofuryl group, dibenzofuryl-d₇ group, quinolyl group, quinolyl-d₆ group, isoquinolyl group, quinoxalinyl group, naphthylidinyl group, quinazolinyl group, phenanthridinyl group, indolidinyl group, phenadinyl group, carbazolyl group, oxazolyl group, oxadiazolyl group, thiazolyl group, thiadiazolyl group, acridinyl group, and phenazinyl group.

The above-described aromatic group in which two rings are fused and the heterocyclic group may include an additional substituent group, and examples thereof include, but are not limited to, an alkyl group such as methyl group, ethyl group, propyl group and tert-butyl group, an aryl group such as phenyl group and biphenyl group, a heterocyclic group such as thienyl group, pyrrollyl group and pyridyl group, a substituted amino group such as dimethylamino group, diethylamino group, dibenzylamino group, diphenylamino group, ditolylamino group and dianisolylamino group, an alkoxy group such as methoxy group, ethoxy group, propoxy group, 2-ethyl-octyloxy group and benzyloxy group, an aryloxy group such as phenoxy group, 4-tert-butylphenoxy group and thienyloxy group, a halogen atom such as fluorine, chlorine, bromine and iodine, hydroxy group, cyano group, and nitro group.

In the general formula [4], g represents an integer of 0 to 9. When g is 2 or more, plural R₁₂'s may be the same or different from each other.

In the general formula [4], h represents an integer of 0 to 11. When h is 2 or more, plural R₁₃'s may be the same or different from each other.

Hereinafter, specific examples of the second organic compound will be enumerated. However, it is to be noted that the present invention is not limited thereto.

### [Specific Examples of the General Formula [3]]

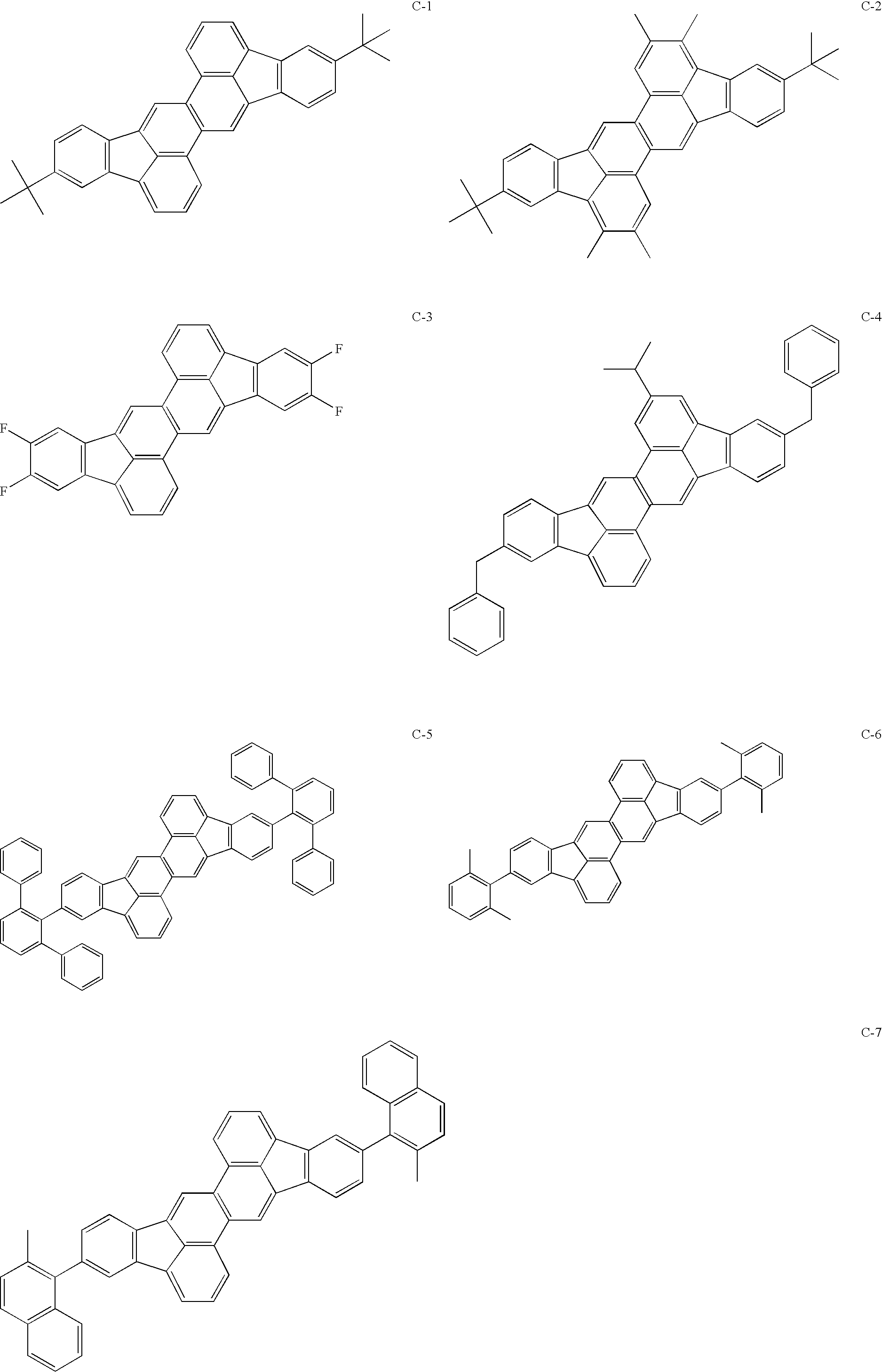

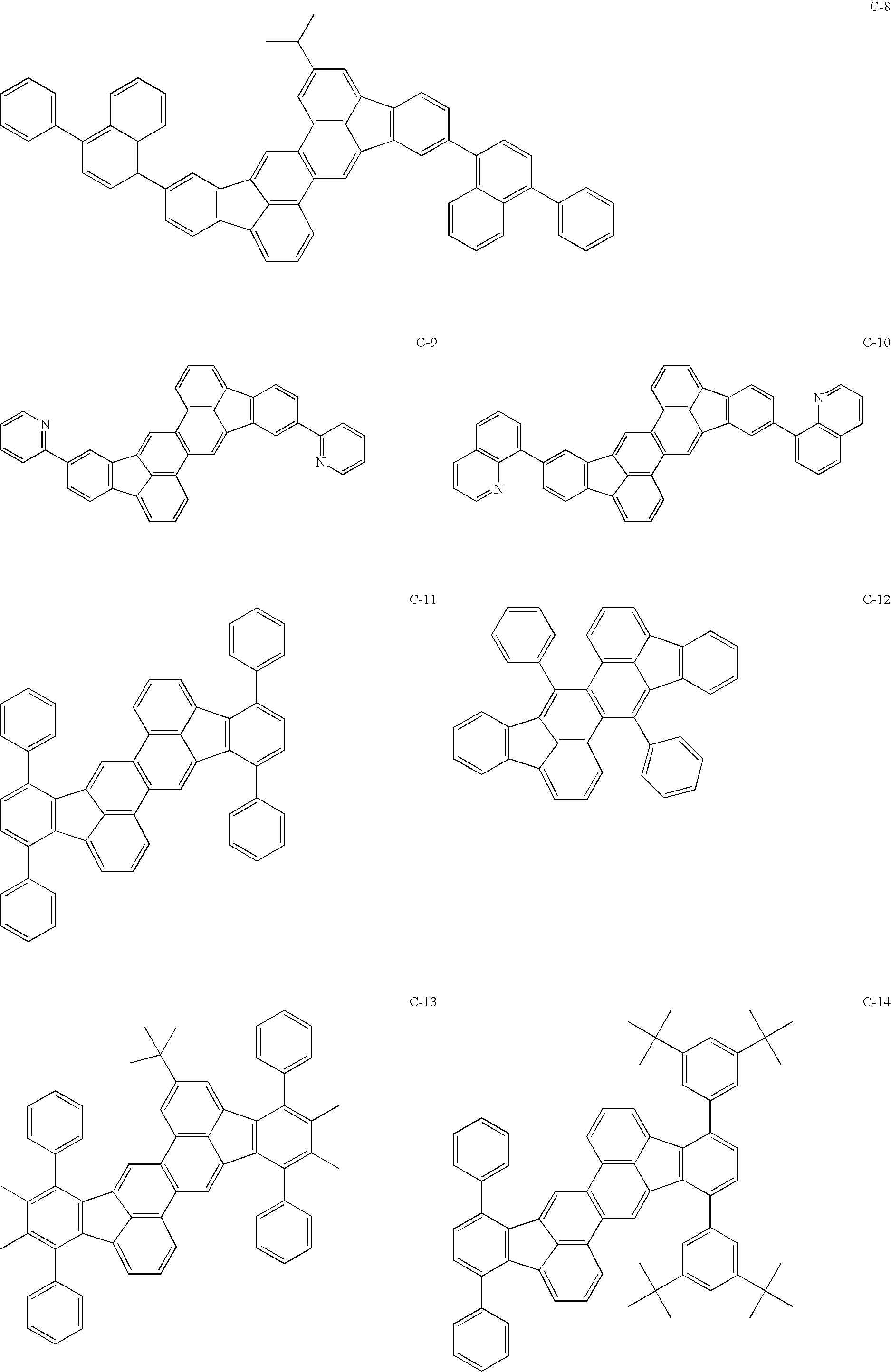

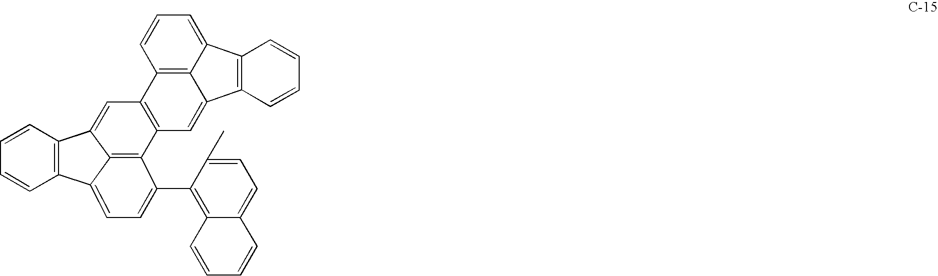

### [Specific Examples of the General Formula [4]]

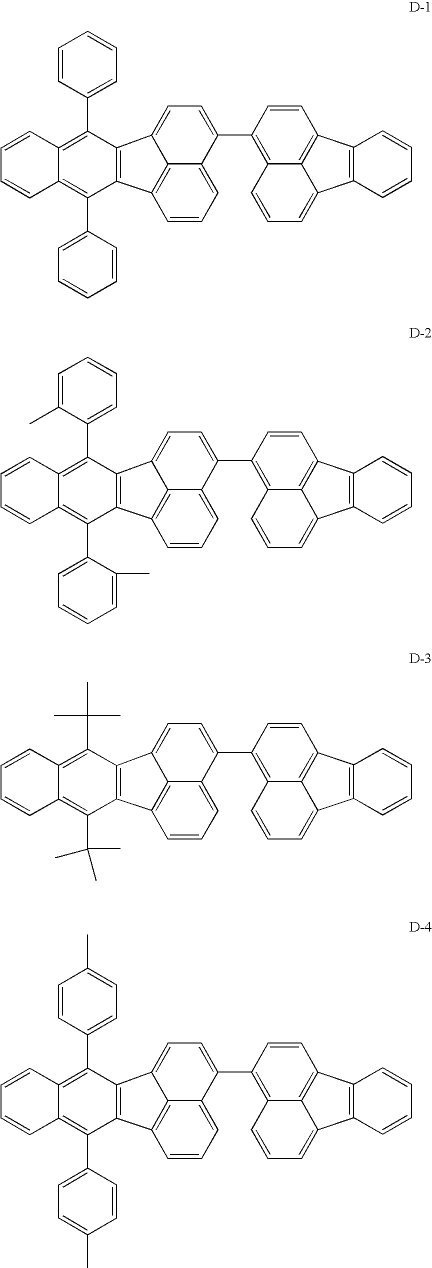

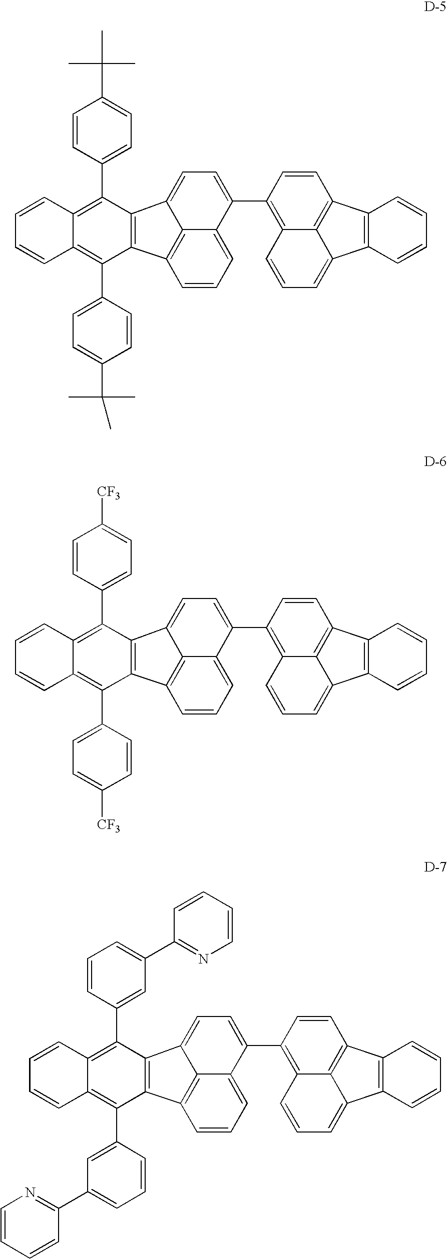

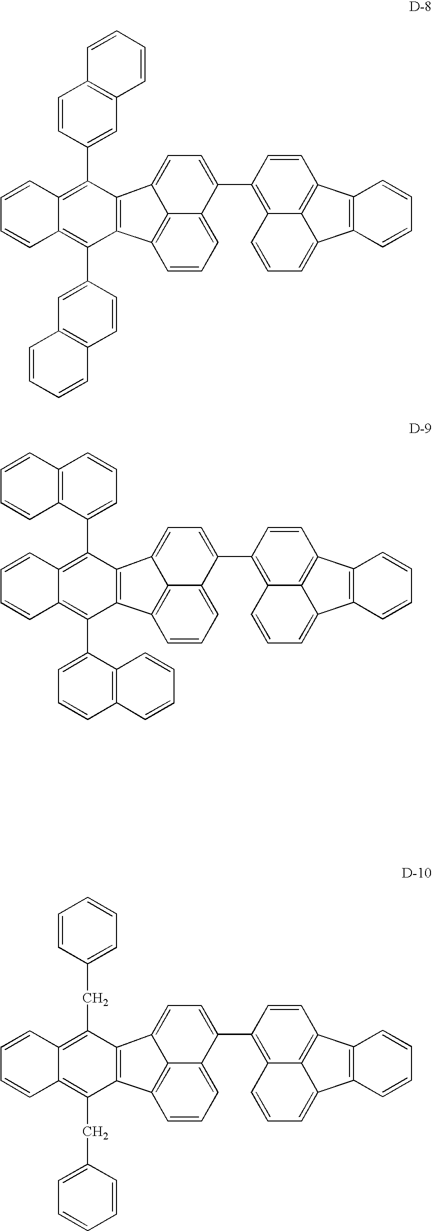

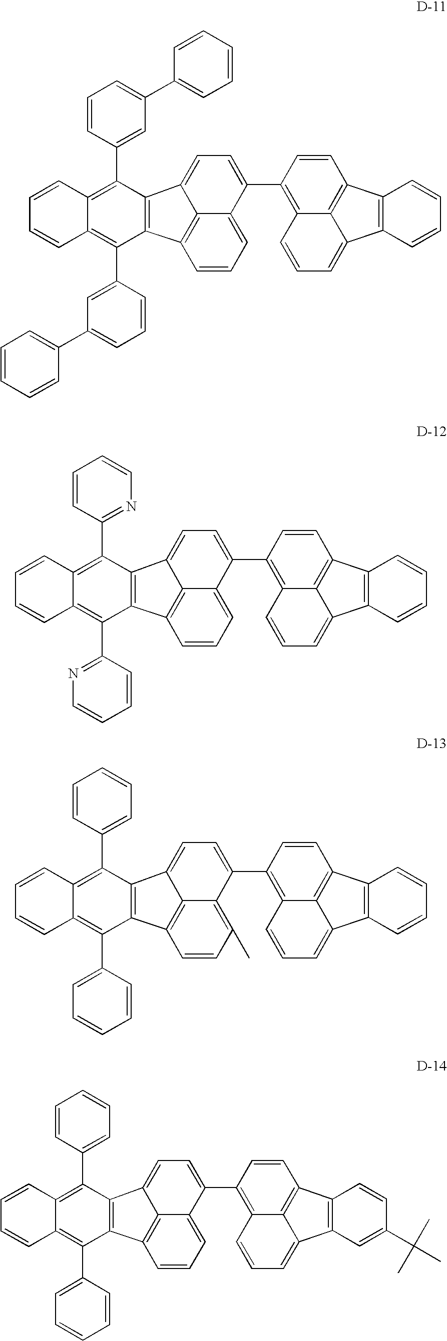

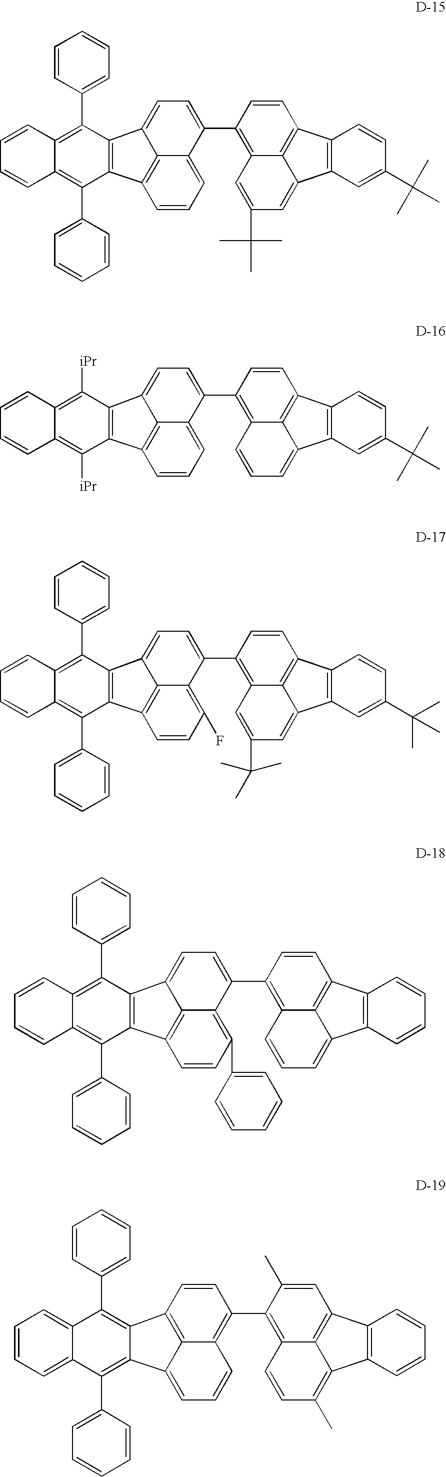

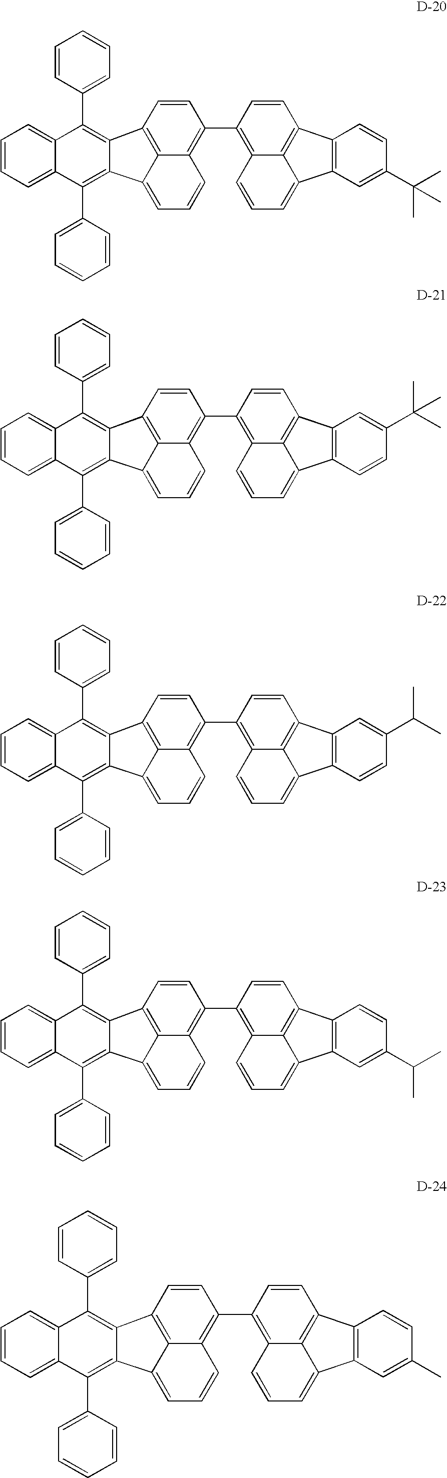

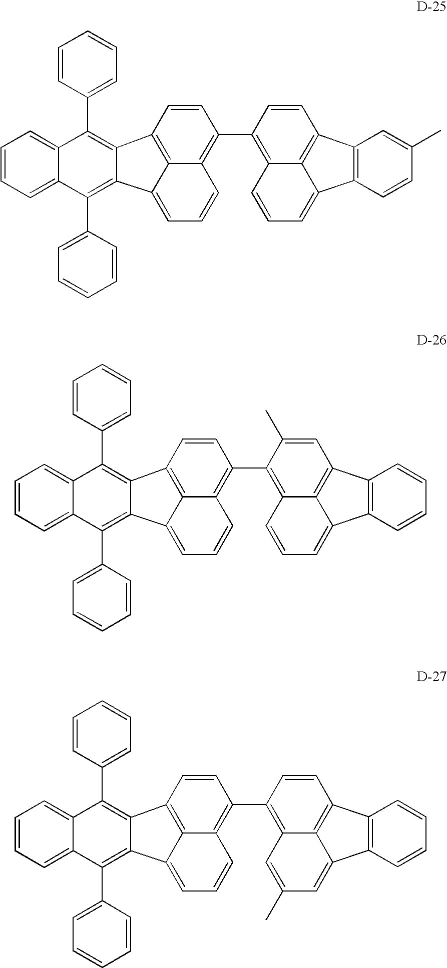

Regarding the compounds of [1] above, the compounds having the following structure are preferred.

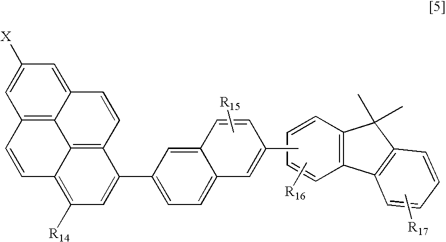

In the general formula [5], R₁₄ represents a hydrogen atom or methyl group. R₁₅ represents a hydrogen atom, methyl group, benzyl group, phenyl group which is unsubstituted or substituted with an alkyl group, or naphthyl group which is unsubstituted or substituted with an alkyl group. R₁₆ and R₁₇ represent a hydrogen atom, tert-butyl group, benzyl group, phenyl group which is unsubstituted or substituted with an alkyl group, or naphthyl group which is unsubstituted or substituted with an alkyl group. R₁₄, R₁₅, R₁₆, and R₁₇ may be the same or different from each other. X is a substituent represented by the following general formula [A]. X is iso-propyl group or tert-butyl group.

Regarding the compounds of [1] above, the compounds having the following structure are also preferred.

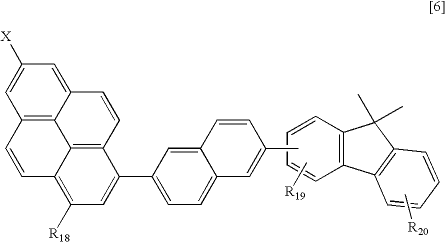

In the general formula [6], R₁₈ represents a hydrogen atom or methyl group. R₁₉ and R₂₀ represent a hydrogen atom, tert-butyl group, benzyl group, phenyl group which is unsubstituted or substituted with an alkyl group, or naphthyl group which is unsubstituted or substituted with an alkyl group. R₁₈ and R₁₉ may be the same or different from each other. X is a substituent represented by the following general formula [A]. X is iso-propyl group or tert-butyl group.

Regarding the compounds of [1] above, the compounds having the following structure are also preferred.

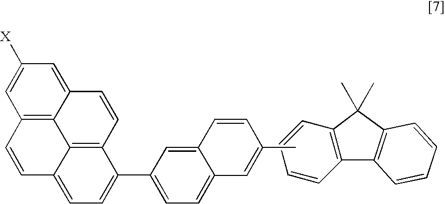

In the general formula [7], X is iso-propyl group or tert-butyl group.

Regarding the compounds of [2] above, the compounds having the following structure are preferred.

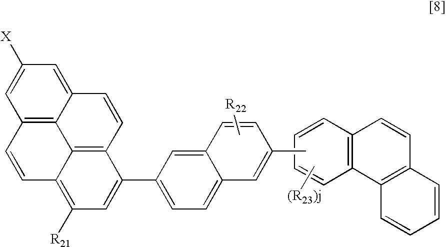

In the general formula [8], R₂₁ represents a hydrogen atom or methyl group. R₂₂ represents a hydrogen atom, methyl group, benzyl group, phenyl group which is unsubstituted or substituted with an alkyl group, or naphthyl group which is unsubstituted or substituted with an alkyl group. R₂₃ represents methyl group, benzyl group, phenyl group which is unsubstituted or substituted with an alkyl group, or naphthyl group which is unsubstituted or substituted with an alkyl group. j is an integer of 0 to 2. R₂₁, R₂₂ and R₂₃ may be the same or different from each other. X is iso-propyl group or tert-butyl group.

Regarding the compounds of [2] above, the compounds having the following structure are also preferred.

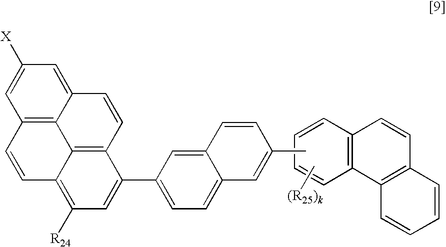

In the general formula [9], R₂₄ represents a hydrogen atom or methyl group. R₂₅ represents methyl group, benzyl group, phenyl group which is unsubstituted or substituted with an alkyl group, or naphthyl group which is unsubstituted or substituted with an alkyl group. j is an integer of 0 to 2. R₂₄ and R₂₅ may be the same or different from each other. X is iso-propyl group or tert-butyl group.

Regarding the compounds of [2] above, the compounds having the following structure are also preferred.

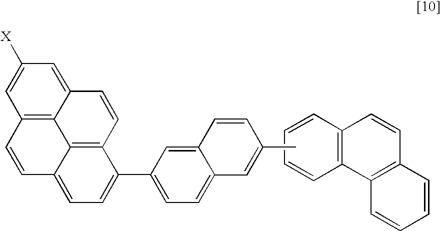

In the general formula [10], X is iso-propyl group or tert-butyl group.

Regarding the compounds of [3] above, the compounds having the following structure are preferred.

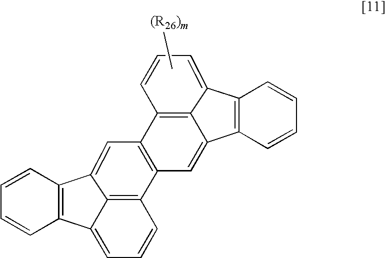

In the general formula [11], R₂₆ represents a halogen atom, alkyl group, benzyl group, a substituted or unsubstituted phenyl group, a substituted or unsubstituted naphthyl group, a substituted or unsubstituted pyridyl group or a substituted or unsubstituted quinolyl group. m is an integer of 0 to 16. When m is 2 or more, plural R₂₆'s may be the same or different from each other.

Regarding the compounds of [3] above, the compounds having the following structure are also preferred.

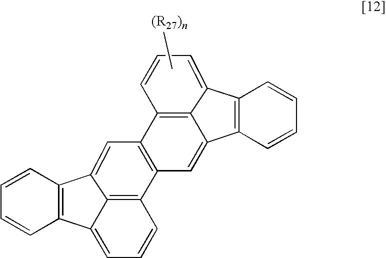

In the general formula [12], R₂₇ is substituted at one or more of the 1-position, 4-position, 7-position, 8-position, 9-position, 12-position, 15-position, or 16-position. R₂₇ represents phenyl group which is unsubstituted or substituted with an alkyl group, or naphthyl group which is unsubstituted or substituted with an alkyl group. n is an integer of 1 to 4. When n is 2 or more, plural R₂₇'s may be the same or different from each other.

Regarding the compounds of [4] above, the compounds having the following structure are preferred.

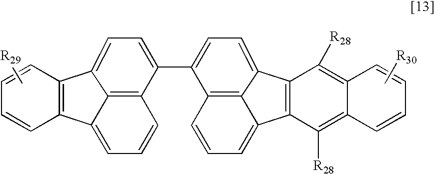

In the general formula [13], R₂₈ represents an alkyl group, benzyl group, a substituted or unsubstituted phenyl group, a substituted or unsubstituted naphthyl group, or a substituted or unsubstituted pyridyl group. R₂₉ and R₃₀ represent a hydrogen atom or an alkyl group. R₂₉ and R₃₀ may be the same or different from each other.

Regarding the compounds of [4] above, the compounds having the following structure are also preferred.

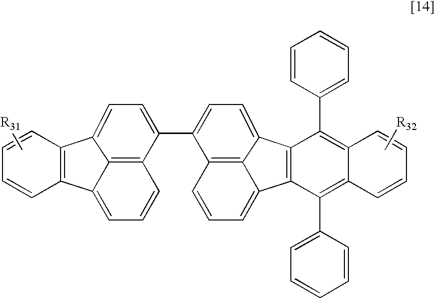

In the general formula [14], R₃₁ and R₃₂ represent a hydrogen atom, or an alkyl group. R₃₁ and R₃₂ may be the same or different from each other.

The concentration of the blue light-emitting dopant included in the layer which forms a light-emitting region is preferably 0.1 wt % or more and 35 wt % or less with respect to the total weight of the blue light-emitting dopant and a host, in consideration of the electron trap mechanism and the energy transfer from the host to the blue light-emitting dopant describe later. More preferably, it is 1 wt % or more and 15 wt % or less.

In general, a compound having a pyrene skeleton has a high electron mobility. Therefore, when such a compound is included in an emission layer, a device can be driven at a low voltage, and also the power efficiency of the device can be improved. In this case, however, a tendency has been known that the ratio between the electrons and the holes in the emission layer (i.e., carrier balance) is disturbed, or a light-emitting region is deviated to the interface of an anode side of the emission layer. Due to such tendency, a reduction in emission efficiency of the device, or the degradation of the device due to continuous driving remains problematic.

In order to solve the above-described problems, in the organic light-emitting device in accordance with the present invention, a compound having a specific fused ring, i.e., the compound represented by the general formula [3] or the general formula [4], is used as a blue light-emitting dopant. In this case, a lowest unoccupied molecular orbital (LUMO) of the blue light-emitting dopant used as a constitutional material for producing the organic light-emitting device of the present invention can be set deeper by 0.35 eV or more (i.e., higher affinity to an electron) than the LUMO of a host. As a result, since the blue light-emitting dopant functions as a strong electron trap, the disruption of carrier balance or the extreme deviation of a light-emitting region can be eliminated.

In addition, when the host and the blue light-emitting dopant that are included in the emission layer of the organic light-emitting device in accordance with the present invention are compared to each other, it is found that the highest occupied molecular orbital (HOMO) of the host is lower than the HOMO of the blue light-emitting dopant (i.e., it has a smaller ionization potential). Therefore, a hole transporting property in the emission layer is mainly provided by the host. Thus, it is specifically required that the radical cation species of the host is chemically stable.

Meanwhile, the cation radicals of pyrene are known to have a huge reaction point at each of the 1-position, 3-position, 6-position and 8-position. In this case, to chemically stabilize cation radical species of a compound having a pyrene skeleton, an aryl group or an alkyl group can be simply introduced to all of the above-described reaction points. However, according to such method, obtainment of an optimum energy gap as a host and optimization of an injection level and mobility for electrons and holes become difficult so that it is disadvantageous in terms of producing a blue light-emitting device which has a high emission efficiency and a long continuous driving lifetime.

Under the circumstance, a substituent is introduced into a pyrene skeleton as shown in the following (i) to (iii). With the following (i) to (iii), the reactivity at each of the reaction positions (i.e., 1-position, 3-position, 6-position and 8-position) can be suppressed.

(i) an aryl group is introduced to the 1-position of the pyrene skeleton
(ii) an alkyl group is introduced to the 3-position of the pyrene skeleton
(iii) a secondary or tertiary alkyl group is introduced to the 7-position of the pyrene skeleton.

In other words, with the procedure of the above (i), the spin density at the 3-position of the pyrene structure can be decreased so that the reactivity of the cation radical of pyrene can be inhibited.

Furthermore, in addition to the above (i), with the procedure of the above (ii), the reactivity of the cation radicals of pyrene can be completely inhibited, which is preferable.

Still further, with the procedure of the above (iii), the reactivity at the 6- and 8-positions of a pyrene skeleton, in which the spin density is high, can be also inhibited due to the steric hindrance of the alkyl group introduced by the above (iii).

Meanwhile, with the above (iii), there can be exhibited the effect including not only that the chemical stability of cation radical species of a pyrene compound as a host is improved but also that the molecular association between pyrene skeletons can be suppressed. For such reasons, an optimum energy gap as a host, an emission spectrum for favorable energy transfer to a blue light-emitting dopant and an amorphous property (i.e., heat resistance) can be obtained.

Meanwhile, with the above (iii), it is also possible to design the highest occupied molecular orbital (HOMO) of a host to be shallow (i.e., to have a lower ionization potential). Thus, the lowest unoccupied molecular orbital (LUMO) of the host can also become shallow (i.e., to have a decreased affinity to an electron). As a result, it is possible to more easily design a host that is required for obtaining optimized carrier injection level for holes and electrons, and a strong electron trapping property in combination with a blue light-emitting dopant.

For the reasons as described above, the host represented by the general formula [1] or the general formula [2] is appropriate for obtaining optimized carrier injection level and mobility for holes and electrons. In addition, the host has an optimum energy gap as a host for blue light-emission, and a lowest unoccupied molecular orbital (LUMO) for obtaining a strong electron trapping property in combination with a blue light-emitting dopant.

In addition, according to molecular orbital calculation, a host represented by the general formula [1] or the general formula [2] has a HOMO orbital localized at a pyrene skeleton. Furthermore, although the LUMO orbital is somewhat spread to the naphthalene side, it is almost localized at a pyrene skeleton, too. Thus, with respect to the compound represented by the general formula [1] or the general formula [2], it is preferable to introduce a substitutent at positions of R₂, R₃, R₄, R₆, and R₇. This is because, scarcely affecting any of a carrier injection level, a band gap and an electron trapping property, molecular association can be suppressed and the amorphous property can be improved.

The blue light-emitting dopant, which is represented by the general formula [3] and the general formula [4] and included in an emission layer of the organic light-emitting device of the present invention, has a high emission quantum yield by itself. As such, it can contribute to increase in the emission quantum yield of the organic light-emitting device. Furthermore, in the blue light-emitting dopant represented by the general formula [3] and the general formula [4], two substituents each having a fluoranthene skeleton are linked by a single bond or a fused ring is formed by condensing two adjacent fluoranthene skeletons. As a result, it is possible to have a deep LUMO (i.e., higher affinity to an electron). Consequently, this light-emitting dopant functions as a strong electron trap, and therefore the disruption of carrier balance or extreme deviation of a light-emitting region can be avoided. At the same time, the emission efficiency or continuous driving lifetime of the device can be improved.

Furthermore, since the blue light-emitting dopant represented by the general formula [3] and the general formula [4] has a substituent which may cause steric hindrance, concentration quenching and a shift of light emission to a longer wavelength side due to an interaction between fused ring aromatic skeletons of a molecule are inhibited and also quantum yield is improved. In particular, by introducing a substituent at the 1-position, 4-position, 7-position, 8-position, 9-position, 12-position, 15-position or 16-position of the compound of the general formula [3], it becomes more easier for the introduced substituent to be aligned perpendicular to a plane that is formed by a fused ring skeleton of the general formula [3]. Furthermore, by introducing a substituent at the 7-position, 12-position of the benzo[k]fluoranthene ring of the general formula [4] in particular, it becomes more easier for the introduced substituent to be aligned perpendicular to a plane that is formed by the benzo[k]fluoranthene ring of the general formula [4]. Furthermore, by introducing a substituent at the other positions of the compound of the general formula [4] (for example the 4-position of a benzo[k]fluoranthene ring, the 2-position, 5-position, 6-position, 8-position, 9-position of a fluoranthene ring), molecular association can be more easily suppressed. Thus, with introduction of these substituents, reduction in emission efficiency due to the molecular association can be prevented.

Still further, introducing a substituent to the 4-position of a benzo[k]fluoranthene ring, the 2-position, 5-position of a fluoranthene ring of the compound of the general formula [4] is effective for inhibiting a change in chemical structure due to purification by sublimation, evaporation, or heat generated during driving of a device, etc. There is a possibility of causing a cyclization reaction based on a chemical bonding caused by heat between the 4-position of a benzo[k]fluoranthene ring and the 4-position of a fluoranthene ring in the compound of the general formula [4]. Since a compound produced by such a cyclization reaction has a significantly longer wavelengths both for absorption and emission, it may absorb EL emission and consequently lower the emission efficiency. Thus, introducing a substituent to the above-described positions of the compound of the general formula [4] is also effective to provide steric hindrance, thus also suppressing the cyclization reaction.

Next, the other constitutional elements which constitute the organic light-emitting device in accordance with the present invention will be explained.

A hole injection/transporting material preferably has excellent mobility for facilitating the injection of holes from an anode and transporting the injected holes to an emission region layer. Examples of a low molecular weight material and a high molecular weight material each having a hole injection/transporting property include, but are not limited to, a triarylamine derivative, a phenylenediamine derivative, a triazole derivative, an oxadiazole derivative, an imidazole derivative, a pyrazoline derivative, a pyrazolone derivative, an oxazole derivative, a fluorenone derivative, a hydrazone derivative, a stilbene derivative, a phthalocyanine derivative, a porphyrin derivative, poly (vinylcarbazole), poly (silylene), poly (thiophene), and any other conductive polymer.

An electron injection/transporting material can be arbitrarily selected from materials each having a function for facilitating the injection of electrons from a cathode and transporting the injected electrons to the emission region layer, and can be selected in consideration of, for example, a balance with the carrier mobility of a hole transporting material. Examples of a material having electron injection/transporting property include, but are not limited to, an oxadiazole derivative, an oxazole derivative, a thiazole derivative, a thiadiazole derivative, a pyrazine derivative, a triazole derivative, a triazine derivative, a perylene derivative, a quinoline derivative, a quinoxaline derivative, a fluorenone derivative, an anthrone derivative, a phenanthroline derivative, and an organometallic complex. In addition, a material having a large ionization potential can be used also as a hole blocking material.

A material for the anode 2 desirably has as large a work function as possible, and examples of the material that can be used include metal elements such as gold, platinum, silver, copper, nickel, palladium, cobalt, selenium, vanadium, and tungsten, or alloys of these metal elements and metal oxides such as tin oxide, zinc oxide, indium oxide, indium tin oxide (ITO), and indium zinc oxide. A conductive polymer such as polyaniline, polypyrrole, polythiophene, and polyphenylene sulfide can also be used. Each of those electrode substances can be used alone, or two or more of them can be used in combination. In addition, the anode 2 may be constituted of a single layer, or may be constituted of a plurality of layers.

On the other hand, a material for the cathode 5 desirably has as small a work function as possible, and examples of the material that can be used include metal elements such as lithium, sodium, potassium, calcium, magnesium, aluminum, indium, ruthenium, titanium, manganese, yttrium, silver, lead, tin, and chromium and alloys comprising two or more of these metal elements. Examples of the alloy include a lithium-indium alloy, a sodium-potassium alloy, a magnesium-silver alloy, an aluminum-lithium alloy, an aluminum-magnesium alloy, and a magnesium-indium alloy. A metal oxide such as indium tin oxide (ITO) can also be used. Each of these electrode substances can be used alone, or two or more of them can be used in combination. In addition, the cathode 5 may be constituted of a single layer, or may be constituted of a plurality of layers.

In addition, at least one of the anode 2 and the cathode 5 is desirably transparent or translucent.

A substrate to be used for the organic light-emitting device of the present invention is not particularly limited, but an opaque substrate such as a metal substrate and a ceramic substrate or a transparent substrate such as glass, quartz and a plastic sheet can be used. In addition, a color filter film, a fluorescent color conversion filter, a dielectric reflection film, or the like can be used for the substrate to control emission color. In addition, a device can be produced while being connected to a thin film transistor (TFT) formed on a substrate.

Furthermore, TFTs can be arranged two-dimensionally to serve as pixels and used as a display. For example, light-emitting pixels of three colors of, e.g., red, green, and blue can be arranged and used as a full color display.

In addition, with regard to the direction of extracting light from the device, any one of a bottom emission configuration in which is extracted from a substrate side and a top emission configuration in which light is extracted from a side opposite to the substrate side can be employed.

The produced device may be provided with a protective layer or a sealing layer for the purpose of preventing the device from contacting with, for example, oxygen or moisture. Examples of the protective layer include a diamond thin film, an inorganic material film made of, for example, a metal oxide or a metal nitride, a polymer film such as a fluororesin, polyparaxylene, polyethylene, silicone resin, or polystyrene resin, and a photocurable resin. In addition, the device can be covered with glass, a gas impermeable film, a metal, or the like, and the device itself can be packaged with an appropriate sealing resin.

A layer composed of an organic compound in the organic light-emitting device in accordance with the present invention is obtained by any one of various methods. In general, a thin film is formed by a vacuum evaporation method, an ionized evaporation method, sputtering, or plasma CVD. Alternatively, a thin film is formed by dissolving a film material in an appropriate solvent, and subjecting the solution to a known application method (such as a spin coating method, a dipping method, a casting method, an LB method, or an ink jet method). In particular, when a film is formed by the coating method, a film can be formed in combination with an appropriate binder resin.

The above-described binder resin can be selected from a wide variety of binder resins, and examples thereof include, but are not limited to, a polyvinyl carbazole resin, a polycarbonate resin, a polyester resin, a polyallylate resin, a polystyrene resin, an ABS resin, a polybutadiene resin, a polyurethane resin, an acrylic resin, a methacrylic resin, a butyral resin, a polyvinyl acetal resin, a polyamide resin, a polyimide resin, a polyethylene resin, a polyether sulfone resin, a diallyl phthalate resin, a phenol resin, an epoxy resin, a silicone resin, a polysulfone resin, and a urea resin. Furthermore, these binder resins can be either a homopolymer or a copolymer. Furthermore, they can be used alone or in combination of two or more. Still further, as required, a known additive such as a plasticizer, an antioxidant, or a UV absorber may be used in combination with the binder resin.

### EXAMPLES

Hereinafter, the present invention will be described more specifically by way of the following Examples. However, the present invention is not limited to these Examples.

### Synthesis Example 1

### Method for Synthesis of Exemplified Compound A2

Exemplified compound A2 was synthesized according to a synthesis scheme shown below.

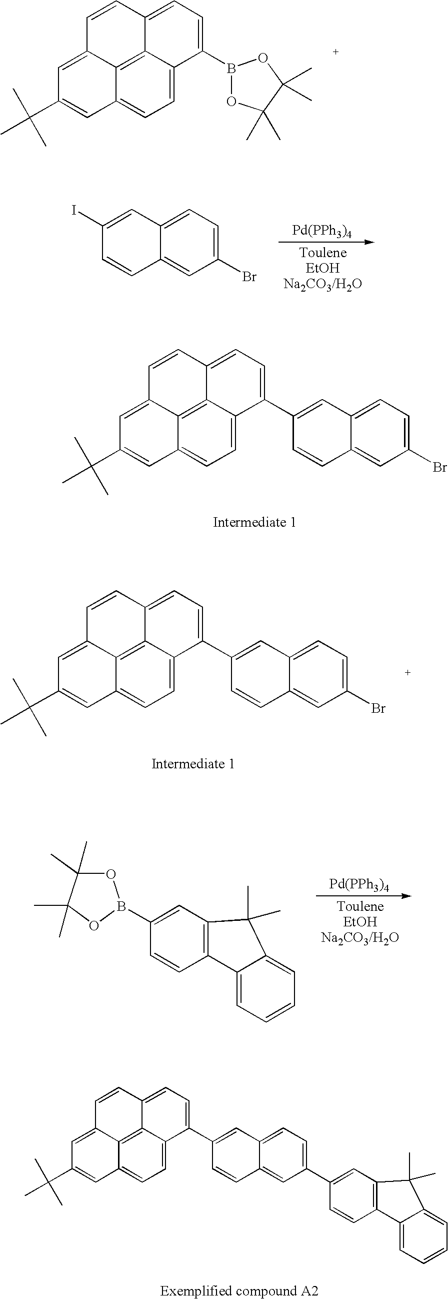

### (1) Synthesis of Intermediate 1

In a reaction vessel, the following reagents and solvent were placed.
2-(7-tert-butylpyren-1-yl)-4,4,5,5-tetramethyl-[1,3,2]dioxaborane: 2.70 g (7.02 mmol)
2-bromo-6-iodonaphthalene: 2.57 g (7.72 mmol)
toluene: 70 ml
ethanol: 35 ml

Next, the reaction mixture was stirred to dissolve solid matters followed by addition of the following reagents, solvent and the like into the reaction vessel.
tetrakistriphenylphosphine palladium: 0.41 g (0.35 mmol)
10% aqueous solution of sodium carbonate: 35 ml

Then, the reaction solution was stirred for 3 hours under heating and reflux. The reaction solution was cooled down to room temperature and then subjected to liquid-liquid separation. As a result, an organic phase was separated, which was then washed with water and dried over sodium sulfate. By evaporating the solvent under reduced pressure, a crude product was obtained. The thus obtained crude product was purified by silica gel column chromatography (developing solvent: toluene/heptane=1/30) to obtain Intermediate 1 (2.23 g, yield: 89.2%).

The structure was determined based on NMR measurement. Peaks identified are described below.

¹H-NMR (500 MHz, CDCl₃): δ (ppm)=8.25-8.20 (m, 3H), 8.14-8.12 (m, 2H), 8.09 (m, 2H), 8.05 (s, 1H), 8.02-8.00 (m, 2H), 7.93 (d, 1H), 7.82-7.79 (m, 2H), 7.63 (dd, 1H), 1.58 (s, 9H)

### (2) Synthesis of Intermediate 2

In a reaction vessel, the following reagents and solvent were placed.
Intermediate 1: 600 mg (1.29 mmol)
2-(9,9-dimethyl-9H-fluoren-2-yl)-4,4,5,5-tetramethyl-[1,3,2]dioxaborane: 456 mg (1.42 mmol)
toluene: 30 ml
ethanol: 15 ml

Next, the reaction mixture was stirred to dissolve solid matters followed by addition of the following reagents and solvent, and the like into the reaction vessel.
tetrakistriphenylphosphine palladium: 74.5 mg (0.06 mmol)
10% aqueous solution of sodium carbonate: 15 ml

Then, the reaction solution was stirred for 2.5 hours under heating and reflux. The reaction solution was cooled down to room temperature and then subjected to liquid-liquid separation. As a result, an organic phase was separated, which was then washed twice with water and dried over sodium sulfate. By evaporating the solvent under reduced pressure, a crude product was obtained. The thus obtained crude product was purified by silica gel column chromatography (developing solvent: toluene/heptane=1/10) to obtain Exemplified Compound A2 (585 mg, yield: 78.4%).

The structure was determined based on NMR measurement. Peaks identified are described below.

¹H-NMR (500 MHz, CDCl₃): δ (ppm)=8.25-8.21 (m, 5H), 8.12-8.10 (m, 4H), 8.07-8.01 (m, 3H), 7.91 (dd, 1H), 7.87 (d, 1H), 7.84-7.76 (m, 4H), 7.48 (d, 1H), 7.40-7.33 (m, 2H), 1.60 (s, 6H) 1.59 (s, 9H)

Meanwhile, in accordance with a synthetic route in which a pyrenyl group is introduced after a fluorenyl group is introduced into 2-bromo-6-iodonaphthalene, Exemplified Compound A2 can be synthesized similarly.

In addition, by using 2-(7-tert-butyl-3-methylpyren-1-yl)-4,4,5,5-tetramethyl-[1,3,2]dioxaborane instead of 2-(7-tert-butylpyren-1-yl)-4,4,5,5-tetramethyl-[1,3,2]dioxaborane, Exemplified Compound A1 can be obtained in the same manner as Synthesis Example 1 (1).

In addition, by using 6-bromo-2-iodo-5-methylnaphthalene instead of 2-bromo-6-iodonaphthalene, Exemplified Compound A13 can be obtained in the same manner as Synthesis Example 1 (1).

### Synthesis Example 2

### Method for Synthesis of Exemplified Compound A4

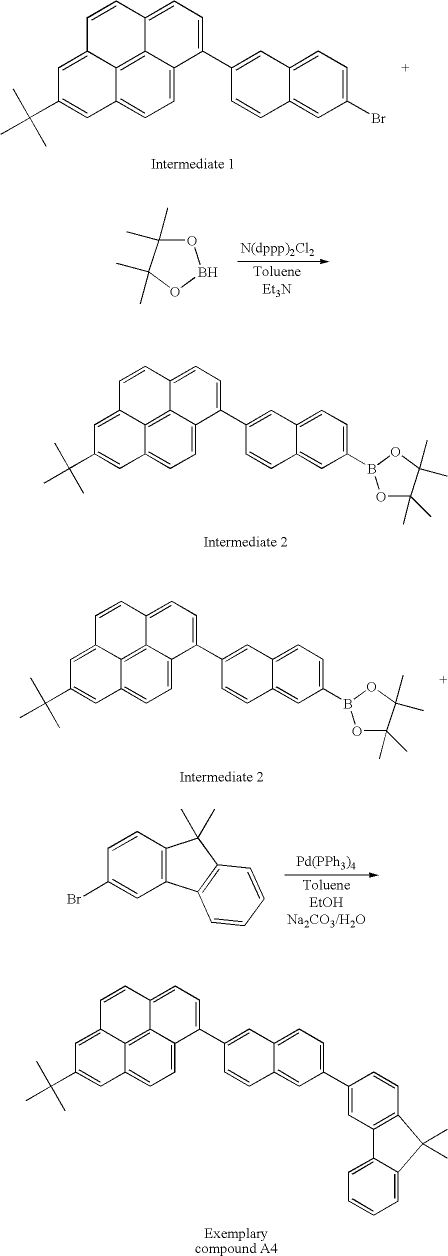

### (1) Synthesis of Intermediate 2

After establishing a nitrogen atmosphere in a reaction vessel, the following reagents and solvent were added thereto.
Intermediate 1: 2.32 g (5.01 mmol)
[1,3-bis(diphenylphosphino)propane]-dichloro nickel: 0.543 g (1.00 mmol)
toluene (anhydrous): 90 ml
triethylamine: 2.08 ml (15.0 mmol)
4,4,5,5-tetramethyl-[1,3,2]dioxaborane: 2.18 ml (15.0 mmol)

Then, the reaction solution was stirred for 4.5 hours while heated at 100° C. The reaction was quenched by adding water to the reaction solution, which was then subjected to liquid-liquid separation. As a result, an organic phase was separated, which was then dried over sodium sulfate. By evaporating the solvent under reduced pressure, a crude product was obtained. The thus obtained crude product was purified by silica gel column chromatography (developing solvent: toluene/heptane=1/1) to obtain Intermediate 2 (1.82 g, yield: 71.1%).

The structure was determined based on NMR measurement. Peaks identified are described below.

¹H-NMR (500 MHz, CDCl₃): δ (ppm)=8.49 (s, 1H), 8.25-8.18 (m, 4H), 8.09-8.00 (m, 6H), 7.93 (m, 2H), 7.78 (dd, 1H), 1.59 (s, 9H), 1.43 (s, 12H)

### (2) Synthesis of Exemplified Compound A4

The following reagents and solvent were placed in a reaction vessel.
Intermediate 2: 523 mg (1.03 mmol)
3-bromo-9,9-dimethyl-9H-fluorene: 308 mg (1.13 mmol)
toluene: 16 ml
ethanol: 8 ml

Next, the reaction mixture was stirred to dissolve solid matters followed by addition of the following reagents, solvent and the like to the reaction vessel.
tetrakistriphenylphosphine palladium: 65.1 mg (0.056 mmol)
10% aqueous solution of sodium carbonate: 8 ml

Then, the reaction solution was stirred for 3 hours under heating and reflux. The reaction solution was cooled down to room temperature and then subjected to liquid-liquid separation. As a result, an organic phase was separated, which was then washed twice with water and dried over sodium sulfate. By evaporating the solvent under reduced pressure, a crude product was obtained. The thus obtained crude product was purified by silica gel column chromatography (developing solvent: toluene/heptane=1/10) to obtain Exemplified Compound A4 (491 mg, yield: 75.5%).

The structure was determined based on NMR measurement. Peaks identified are described below.

¹H-NMR (500 MHz, CDCl₃): δ (ppm)=8.25-8.22 (m, 5H), 8.14-8.11 (m, 5H), 8.08-8.02 (m, 3H), 7.93 (dd, 1H), 7.87 (d, 1H), 7.83 (dd, 1H), 7.74 (dd, 1H), 7.59 (d, 1H), 7.49 (d, 1H), 7.42-7.36 (m, 2H), 1.60 (s, 9H), 1.58 (s, 6H)

### Synthesis Example 3

### Method for Synthesis of Exemplified Compound B5

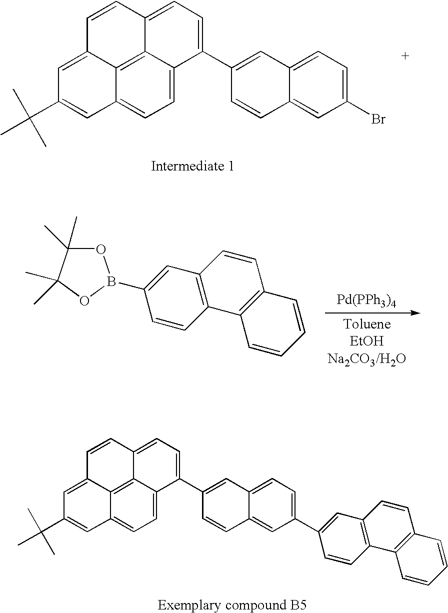

### (1) Synthesis of Exemplified Compound B5

The following reagents and solvent were placed in a reaction vessel.
Intermediate 1: 500 mg (1.08 mmol)
4,4,5,5-tetramethyl-2-phenanthren-2-yl-[1,3,2]dioxaborane: 361 mg (1.19 mmol)
toluene: 16 ml
ethanol: 8 ml

Next, the reaction mixture was stirred to dissolve solid matters followed by addition of the following reagents, solvent and the like to the reaction vessel.
tetrakistriphenylphosphine palladium: 62.3 mg (0.05 mmol)
10% aqueous solution of sodium carbonate: 8 ml

Then, the reaction solution was stirred for 3.5 hours under heating and reflux. The reaction solution was cooled down to room temperature and then subjected to liquid-liquid separation. As a result, an organic phase was separated, which was then washed with water and dried over sodium sulfate. By evaporating the solvent under reduced pressure, a crude product was obtained. Incidentally, this crude product includes a catalyst. The thus obtained crude product was purified by silica gel column chromatography (developing solvent: toluene/heptane=1/10) to remove the catalyst. Further purification was carried out by recrystallization by using a mixed solvent comprising chloroform and ethanol (chloroform/ethanol=16/1) to obtain Exemplified Compound B5 (500 mg, yield: 82.6%).

The structure was determined based on NMR measurement. Peaks identified are described below.

¹H-NMR (500 Hz, CDCl₃): δ (ppm)=8.84 (d, 1H), 8.76 (d, 1H), 8.36 (s, 1H), 8.31 (s, 1H), 8.26-8.22 (m, 4H), 8.16-8.07 (m, 7H), 8.05-8.02 (m, 2H), 7.94 (d, 1H), 7.90-7.82 (m, 3H), 7.70 (t, 1H), 7.64 (t, 1H), 1.60 (s, 9H)

### Synthesis Example 4

### Method for Synthesis of Exemplified Compound B3

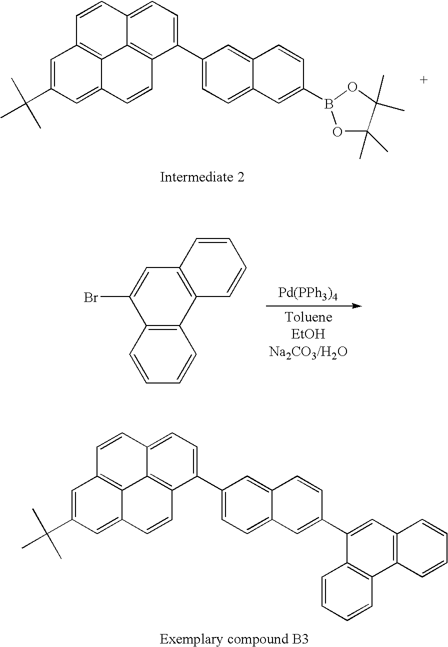

### (1) Synthesis of Exemplified Compound B3

The following reagents and solvent were placed in a reaction vessel.
Intermediate 2: 523 mg (1.02 mmol)
9-bromophenanthrene: 258 mg (1.00 mmol)
toluene: 40 ml
ethanol: 20 ml

Next, the reaction mixture was stirred to dissolve solid matters followed by addition of the following reagents, solvent and the like to the reaction vessel.
tetrakistriphenylphosphine palladium: 24 mg (0.02 mmol)
10% aqueous solution of sodium carbonate: 20 ml

Then, the reaction solution was stirred for 4 hours under heating and reflux. The reaction solution was cooled down to room temperature and then subjected to liquid-liquid separation using toluene and water. As a result, an organic phase was separated, which was then washed with water and dried over sodium sulfate. By evaporating the solvent under reduced pressure, a crude product was obtained. The thus obtained crude product was purified by column chromatography based on a chlorobenezene/heptane system. Purified product was concentrated, recrystallized in a toluene/ethanol system, washed with ethanol, and then subjected to suction filtration to obtain Exemplified Compound B3 (450 mg, yield: 80.3%).

The structure was determined based on NMR measurement. Peaks identified are described below.

¹H-NMR (500 Hz, CDCl₃): δ (ppm)=8.84 (d, 1H), 8.78 (d, 1H), 8.24 (dt, 5H), 8.16 (s, 1H), 8.07 (dq, 7H), 7.97 (d, 1H), 7.87 (t, 2H), 7.79-7.65 (m, 4.1H), 7.58 (t, 1H), 1.60 (s, 9H)

### Synthesis Example 5

### Method for Synthesis of Exemplified Compound C7

Exemplified Compound C7 was synthesized according to a synthesis scheme shown below.

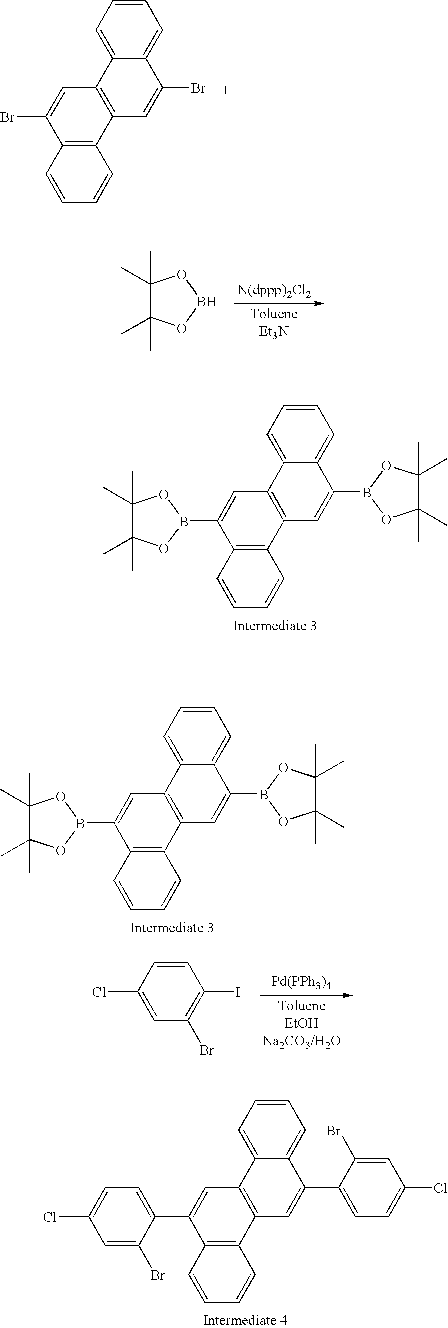

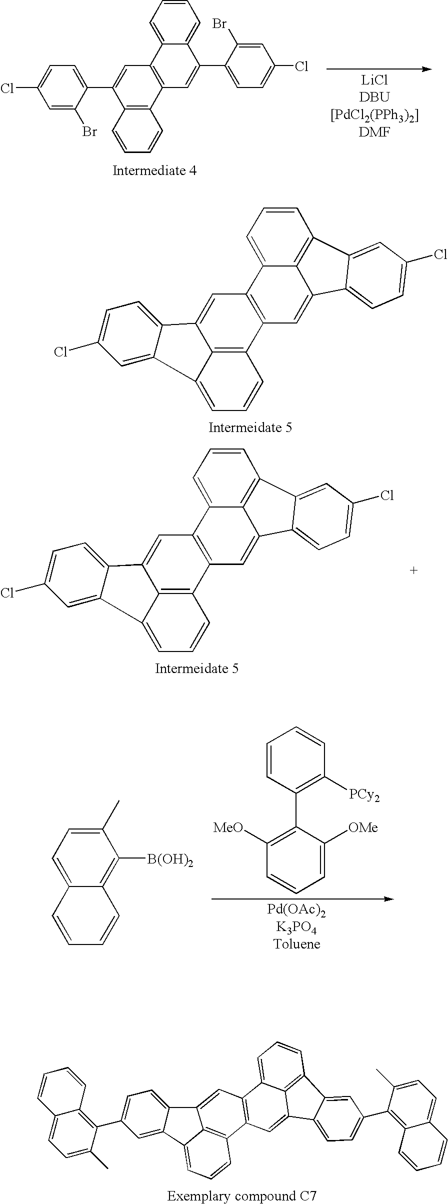

### (1) Synthesis of Intermediate 3

The following reagents and solvent were placed in a 300 ml recovery flask.
6,12-dibromochrysene: 2.5 g (6.48 mmol)
4,4,5,5-tetramethyl-1,3,2-diosaborane: 5.63 ml (38.8 mmol)
[1,3-bis(diphenylphosphino)propane]dichloro nickel (II): 325 mg (0.65 mmol)
toluene: 100 ml
triethylamine: 30 ml

Then, the reaction solution was stirred for 8 hours while heated at 80° C. under nitrogen flow. Upon the completion of the reaction, the reaction solution was cooled down to room temperature followed by addition of water thereto. An aqueous solution of ammonium chloride was added and the resulting reaction solution was stirred as such for three hours. Ethyl acetate and water were added to separate an organic phase, which was then dried over magnesium sulfate. By evaporating the solvent under reduced pressure, a crude product was obtained. The thus obtained crude product was purified by silica gel column chromatography (developing solvent: toluene) to obtain Intermediate 3 (2.1 g, yield: 68%).

### (2) Synthesis of Intermediate 4

The following reagents and solvent were placed in a 300 ml recovery flask.
Intermediate 3: 2.0 g (4.16 mmol)
2-bromo-4-chloro-1-iodobenzene: 2.7 g (8.5 mmol) tetrakistriphenylphosphine palladium (0): 485 mg (0.42 mmol)
toluene: 100 ml
ethanol: 50 ml
2M-aqueous solution of sodium carbonate: 20 ml

Then, the reaction solution was stirred for 4 hours while heated at 80° C. under nitrogen flow. Upon the completion of the reaction, toluene and water were added to the reaction solution to separate an organic phase, which was then dried over magnesium sulfate. By evaporating the solvent under reduced pressure, a crude product was obtained. The thus obtained crude product was purified by silica gel column chromatography (developing solvent: toluene/heptane=1/9) to obtain Intermediate 4 (1.81 g, yield: 72%).

### (3) Synthesis of Intermediate 5

The following reagents and solvent were placed in a recovery flask.
Intermediate 4: 1.5 g (2.47 mmol)
LiCl: 636 mg (15.0 mmol)
1,8-diazabicyclo[5.4.0]7-undecene: 943 mg (6.20 mmol) bistriphenylphosphine palladium (II) dichloride: 40 mg (0.24 mmol)
dimethylformamide: 150 ml

Then, the reaction solution was stirred for 8 hours while heated at 100° C. under nitrogen flow. Upon the completion of the reaction, water was added to the reaction solution followed by stirring for 1 hour at room temperature. After confirming the presence of an orange precipitate in the reaction solution, the precipitate was filtered and washed with water, methanol and acetone in the mentioned order. Next, by drying the filtrate, Intermediate 5 was obtained (1.1 g, yield: 51%).

Molecular weight of the thus obtained compound was measured.

### (Molecular Weight)

With an analysis based on MALDI-TOF-MAS (Matrix Assisted Laser Desorption/Ionization-Time of Flight Mass Spectroscopy), it was confirmed that M+ was 445.3. As a result, Compound Intermediate 5 was identified.

### (4) Synthesis of Exemplified Compound C7

The following reagents and solvent were placed in a recovery flask.
Intermediate 5: 500 mg (1.12 mmol)
2-methylnaphthalene-1-yl boronic acid: 450 mg (2.4 mmol) palladium (II) acetate: 75 mg (0.33 mmol)
2-dicyclohexylphosphino-2′,6′-dimethoxybiphenyl: 410 mg (0.99 mmol)
tripotassium phosphate: 713 mg (3.36 mmol)
toluene: 50 ml

Then, the reaction solution was stirred for 8 hours while heated at 80° C. under nitrogen flow. Upon the completion of the reaction, toluene and water were added to separate an organic phase, which was then dried over magnesium sulfate. By evaporating the solvent under reduced pressure, a crude product was obtained. The thus obtained crude product was purified by silica gel column chromatography (developing solvent: toluene/heptane=1/3) to obtain Exemplified Compound C7 (209 mg, yield: 32%).

The physical properties were evaluated for the thus obtained compound.

With an analysis based on MALDI-TOF-MAS (Matrix Assisted Laser Desorption/Ionization-Time of Flight Mass Spectroscopy), it was confirmed that M+was 656.8. As a result, Exemplified Compound C7 was identified.

The structure of the compound was determined based on NMR measurement. Peaks identified are described below.

¹H-NMR (CDCl₃, 600 MHz) σ (ppm): 9.34 (s, 2H), 8.82 (d, 2H, J=5.8 Hz), 8.30 (d, 2H, J=6.3 Hz), 8.06 (d, 2H, J=5.8 Hz), 7.93-7.86 (m, 8H), 7.62 (d, 2H, J=7.1 Hz), 7.51 (d, 2H, J=7.1 Hz), 7.46-7.39 (m, 6H), 2.40 (s, 6H)

### Synthesis Example 6

### Method for Synthesis of Exemplified Compound C14

Exemplified Compound C14 was synthesized according to a synthesis scheme shown below, for example.

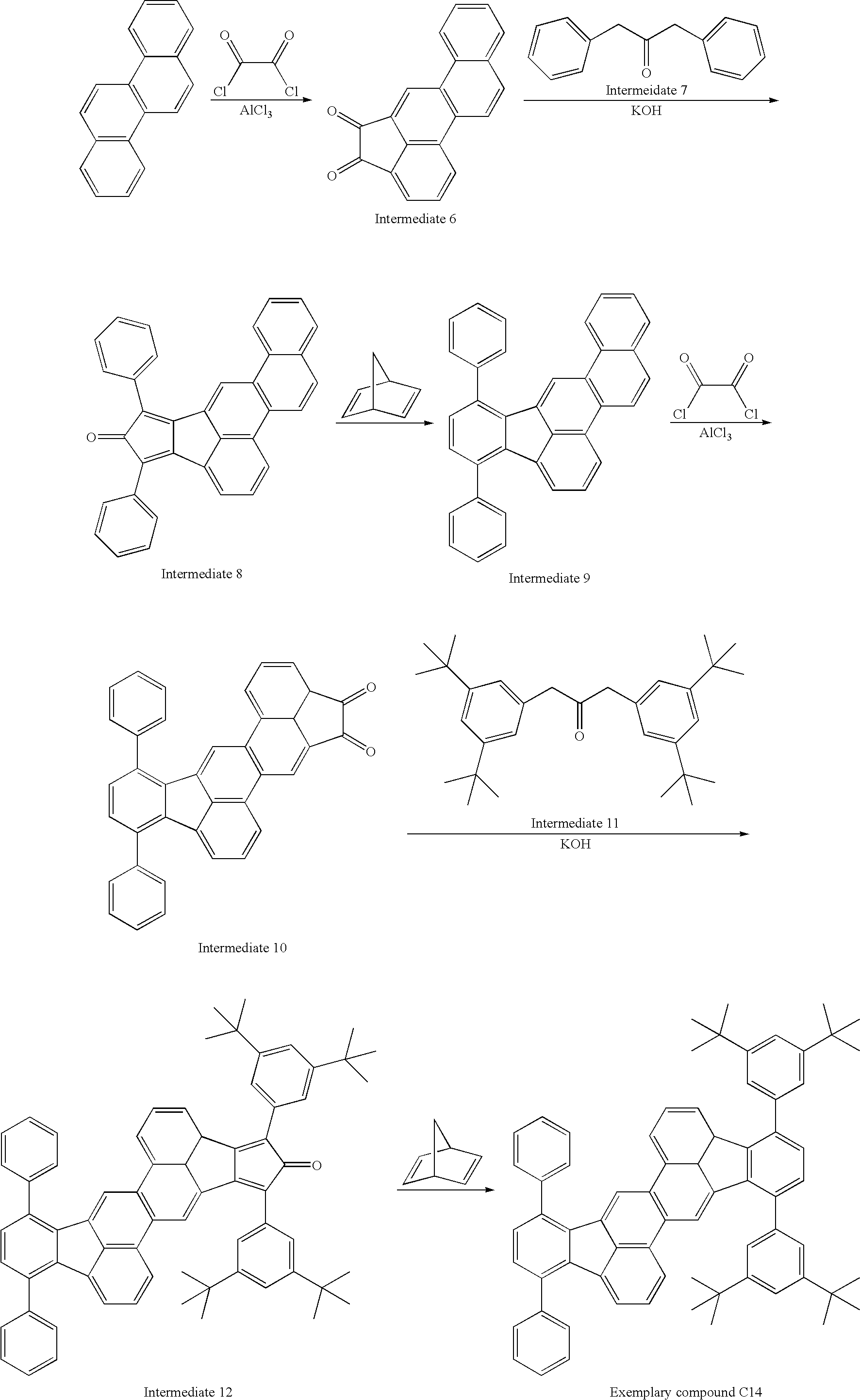

### (1) Synthesis of Intermediate 6

The following reagents and solvent were placed in a 500 ml three-neck flask.
chrysene: 20.0 g (87.6 mmol)
aluminum chloride: 46.7 g (350 mmol)
dichloromethane: 400 ml

Then, while stirring the reaction solution at −78° C. under nitrogen flow, oxalyl chloride (55.6 g, 438 mmol) was added dropwise thereto. Subsequently, while maintaining the reaction solution at this temperature, the reaction solution was stirred for 30 minutes and then the temperature was raised to room temperature over 2 hours. The reaction solution was poured into 4 L ice water while being stirred, and the solid produced therefrom was separated by filtration. Next, the thus obtained solid was dispersed and washed with 100 ml methanol. Finally, the washed solid was filtered and heat-dried under vacuum to obtain Intermediate 6 (orange powder; 21.5 g, yield: 87%).

### (2) Synthesis of Intermediate 8

The following reagents and solvent were placed in a 200 ml three-neck flask.
Intermediate 6: 2.01 g (7.10 mmol)
Intermediate 7: 1.50 g (7.13 mmol)
ethanol: 100 ml

Then, while stirring the reaction solution at room temperature under nitrogen flow, an aqueous solution (25 ml) having potassium hydroxide (4.00 g) dissolved therein was added dropwise thereto. Subsequently, the reaction temperature was raised to 75° C. and the mixture was stirred at the same temperature for 1.5 hours. After cooling the reaction solution, the precipitated solid was separated by filtration and dried to obtain Intermediate 8 (green powder; 3.08 g, yield: 95%).

### (3) Synthesis of Intermediate 9

The following reagents and solvent were placed in a 200 ml three-neck flask.
Intermediate 8: 3.00 g (6.58 mmol)
2,5-norbornadiene: 4.97 g (54 mmol)
acetic acid anhydride: 40 ml

Then, the temperature of the reaction solution was raised to 90° C. under nitrogen flow and the reaction solution was stirred at the same temperature for 18 hours. After cooling the reaction solution to room temperature, the solvent was evaporated under reduced pressure to obtain a crude product. The thus obtained crude product was purified by silica gel column chromatography (developing solvent: mixture of toluene and heptane) to obtain Intermediate 9 (yellow powder; 1.58 g, yield: 53%).

### (4) Synthesis of Intermediate 10

The following reagents and solvent were placed in a 100 ml three-neck flask.
Intermediate 9: 1.00 g (2.20 mmol)
aluminum chloride: 1.06 g (7.92 mmol)
dichloromethane: 50 ml

Then, while stirring the reaction solution at −78° C. under nitrogen flow, oxalyl chloride (1.11 g, 8.80 mmol) was added dropwise thereto. Subsequently, while maintaining the reaction solution at this temperature (78° C.), the reaction solution was stirred for 30 minutes and then the temperature was raised to room temperature over 2 hours. The reaction solution was poured into 1 L ice water while being stirred, and the solid produced therefrom was separated by filtration. Next, the thus obtained solid was dispersed and washed with 30 ml methanol. Finally, the washed solid was filtered and heat-dried under vacuum to obtain Intermediate 10 (orange powder; 0.894 g, yield: 80%).

### (5) Synthesis of Intermediate 12

The following reagents and solvent were placed in a 200 ml three-neck flask.
Intermediate 10: 0.890 g (1.75 mmol)
Intermediate 11: 0.855 g (1.97 mmol)
ethanol: 100 ml
toluene: 10 ml

Then, while stirring the reaction solution at room temperature under nitrogen flow, an aqueous solution (5 ml) having potassium hydroxide (1.11 g) dissolved therein was added dropwise thereto. Subsequently, the reaction temperature was raised to 75° C. and the mixture was stirred at the same temperature for 2.5 hours. After cooling the reaction solution, the precipitated solid was separated by filtration and dried to obtain Intermediate 12 (green powder; 0.49 g, yield: 31%).

### (6) Synthesis of Exemplified Compound C14

The following reagents and solvent were placed in a 200 ml three-neck flask.
Intermediate 12: 0.49 g (0.541 mmol)
2,5-norbornadiene: 4.97 g (54 mmol)
acetic acid anhydride: 40 ml

Then, the reaction solution was stirred for 18 hours while heated at 90° C. under nitrogen flow. After cooling the reaction solution to room temperature, a crude product was obtained by evaporating the solvent under reduced pressure. The thus obtained crude product was purified by silica gel column chromatography (developing solvent: mixed solvent of toluene and heptane) to obtain Exemplified Compound C14 (yellow powder; 0.17 g, yield: 35%).

The physical properties were evaluated for the obtained compound.

With an analysis based on MALDI-TOF-MAS (Matrix Assisted Laser Desorption/Ionization-Time of Flight Mass Spectroscopy), it was confirmed that M+ was 905.5. As a result, Exemplified Compound G-20 was identified. With NMR measurement, the structure of Exemplified Compound G-20 was confirmed.

¹H-NMR (CDCl₃, 400 MHz) σ(ppm): 8.35 (s, 1H), 8.00 (s, 1H), 7.81 (dd, 2H, J=8.4 Hz, J=10.4 Hz), 7.76-7.73 (m, 3H), 7.69-7.64 (m, 5H), 7.56-7.50 (m, 8H), 7.45-7.30 (m, 7H), 7.22 (d, 1H, J=7.2 Hz), 1.42 (s, 18H), 1.40 (s, 18H)

### Synthesis Example 7

### Method for Synthesis of Exemplified Compound D1

Exemplified Compound D1 was synthesized according to a synthesis scheme shown below.

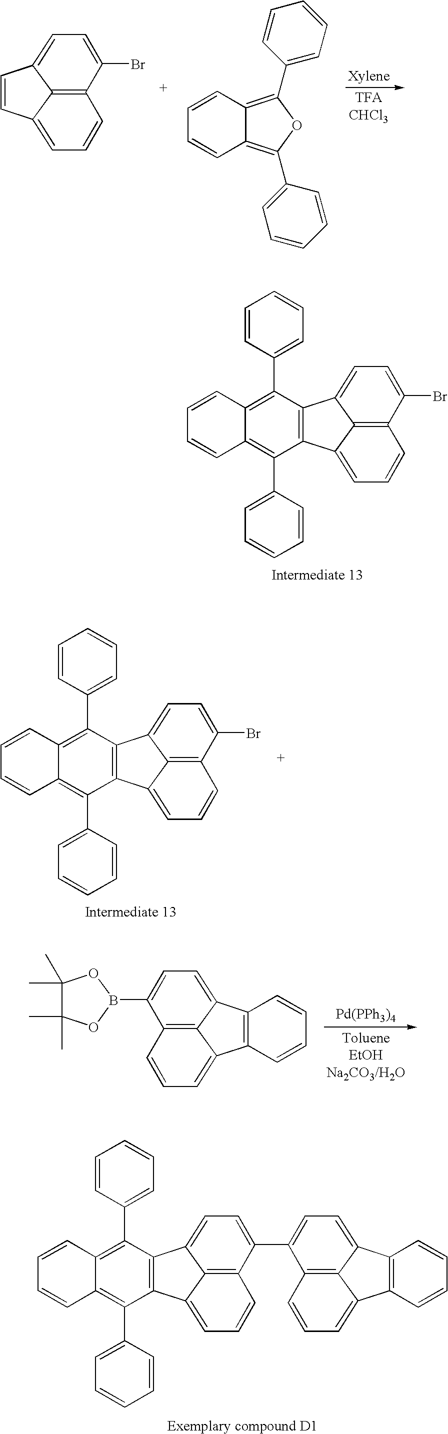

### (1) Synthesis of Intermediate 13

The following reagents and solvent were placed in a reaction vessel.
5-bromoacenaphthylene: 14.5 g (62.8 mmol)
diphenylisobenzofurane: 17.1 g (63.3 mmol)
xylene: 200 ml

Then, the reaction solution was stirred for 5 hours while heated at temperature at which xylene serving as a solvent was refluxed. After cooling the reaction solution to room temperature, the solvent was evaporated under reduced pressure. Next, after adding anhydrous trifluoroacetic acid (26 ml) and chloroform (260 ml), the reaction solution was stirred for 1 hour under reflux. After cooling the reaction solution to room temperature, a residue was obtained by evaporating the solvent under reduced pressure. The thus obtained residue was purified by silica gel column chromatography (developing solvent: toluene/heptane=1/3) to obtain Intermediate 13 as a yellow solid (16 g).

### (2) Synthesis of Exemplified Compound D1

After establishing nitrogen atmosphere in a reaction vessel, the following reagents and solvent were added thereto.
4-bromo-7,12-diphenylbenzo[k]fluoranthene: 0.7 g (1.45 mmol)
2-(fluoranthen-3-yl)-4,4,5,5-tetramethyl-[1,3,2]dioxaborolane: 0.48 g (1.45 mmol)
toluene: 100 ml
ethanol: 50 ml

Next, an aqueous solution having cesium carbonate (0.95 g, 2.90 mmol) dissolved in 15 ml of distilled water was added to the reaction solution followed by stirring the reaction solution for 30 minutes while heated at 50° C.

Tetrakis(triphenylphosphine)palladium (0.17 g, 0.145 mmol) was added to the reaction solution, which was then heated in a silicone oil bath (90° C.) and stirred for 5 hours. The reaction solution was cooled down to room temperature, and then an organic phase was separated by adding water, toluene, and ethyl acetate thereto. In addition, by carrying out extraction of an aqueous phase twice by using a mixed solvent of toluene and ethyl acetate, the thus obtained organic phase was combined with the organic phase which had been originally isolated. The thus combined organic phase was washed with saturated brine and dried over sodium sulfate. Then, a residue was obtained by evaporating the solvent contained in the organic phase under reduced pressure. The thus obtained residue was purified by silica gel column chromatography (developing solvent: toluene/heptane=1/3) to obtain a crystal. Finally, the thus obtained crystal was dried at 120° C. under vacuum and further purified by sublimation to obtain Exemplified Compound D1 as a bright yellow solid (0.6 g).

With an analysis based on MALDI-TOF-MS (Matrix Assisted Laser Desorption/Ionization-Time of Flight Mass Spectroscopy), it was confirmed that M+was 604.7 for the compound.

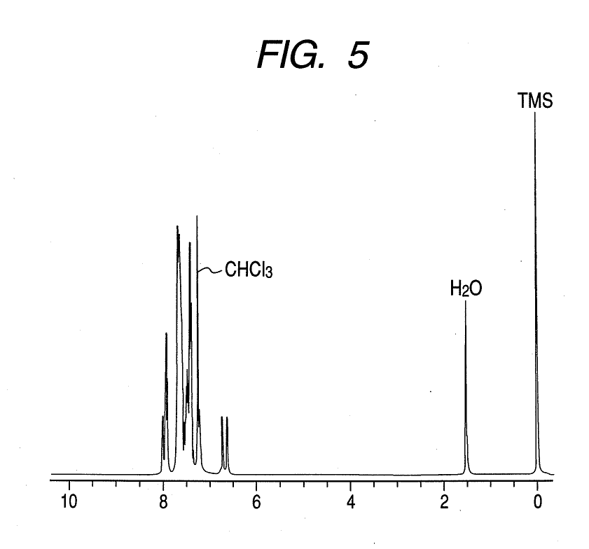

With ¹H-NMR measurement, a NMR spectrum as shown in FIG. 5 was obtained, and therefore the structure of this compound was confirmed.

### Synthesis Example 8

### Method for Synthesis of Exemplified Compound D19

Exemplified Compound D19 was synthesized according to a synthesis scheme shown below.

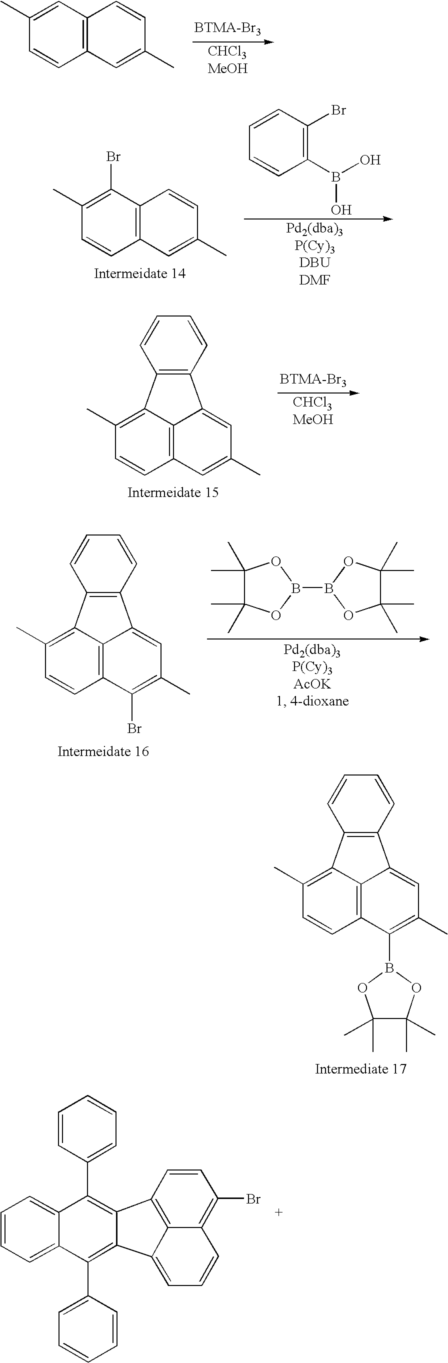

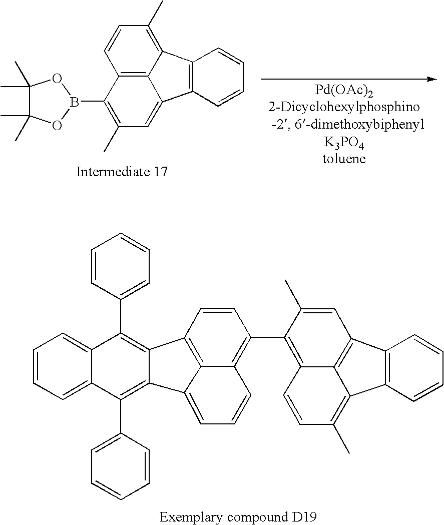

### (1) Synthesis of Intermediate 14

The following reagents and solvent were placed in a reaction vessel.
2,6-dimethylnaphthalene: 5.00 g (32.0 mmol)
chloroform: 50 ml
methanol: 50 ml

Then, the reaction mixture was stirred to dissolve solid matters followed by cooling down the mixture in an ice bath. Subsequently, the following reagent was added to the reaction vessel.
benzyltrimethylammonium tribromide: 12.5 g (32.0 mmol)

Then, the reaction solution was stirred for 12 hours while the temperature was raised slowly to room temperature. The reaction solution was subjected to liquid-liquid separation. As a result, an organic phase was separated, which was then washed with water and dried over sodium sulfate. By evaporating the solvent under reduced pressure, a crude product was obtained. The thus obtained crude product was purified by silica gel column chromatography (developing solvent: heptane) to obtain Intermediate 14 (4.89 g, yield: 65.0%).

### (2) Synthesis of Intermediate 15

The following reagents and solvent were placed in a reaction vessel.
dipalladium (0) tris(dibenzylidene acetone): 2.54 g (2.775 mmol)
tricyclohexylphosphine: 2.08 g (7.40 mmol)
N,N-dimethylformamide: 30 ml

Then, the reaction mixture was stirred at room temperature for 15 minutes and the following reagents were further added to the reaction vessel.
Intermediate 14: 4.50 g (18.5 mmol)
2-bromophenylboronic acid: 4.46 g (22.2 mmol)
8-diazabicyclo[5.4.0]-unde-7-cene: 13.8 ml (92.5 mmol)

Then, the reaction solution was stirred for 12 hours while heated at 155° C. under nitrogen flow. The reaction solution was then cooled down to room temperature. After the filtration of the reaction solution, the filtrate solution was subjected to liquid-liquid separation. As a result, an organic phase was separated, which was then washed with water and dried over sodium sulfate. By evaporating the solvent under reduced pressure, a crude product was obtained. The thus obtained crude product was purified by silica gel column chromatography (developing solvent: heptane) to obtain Intermediate 15 (1.42 g, yield: 33.3%).

### (3) Synthesis of Intermediate 16

The following reagents and solvent were placed in a reaction vessel.
Intermediate 15: 1.20 g (5.21 mmol)
chloroform: 8 ml
methanol: 8 ml

Then, the reaction mixture was stirred to dissolve solid matters followed by cooling down the mixture in an ice bath. Subsequently, the following reagent was added to the reaction vessel.
benzyltrimethylammonium tribromide: 2.03 g (5.21 mmol)

Then, the reaction solution was stirred for 18 hours while the temperature was raised slowly to room temperature. The reaction solution was subjected to liquid-liquid separation. As a result, an organic phase was separated, which was then washed with water and dried over sodium sulfate. By evaporating the solvent under reduced pressure, a crude product was obtained. The thus obtained crude product was purified by silica gel column chromatography (developing solvent: heptane) to obtain Intermediate 16 (0.93 g, yield: 57.6%).

### (4) Synthesis of Intermediate 17

The following reagents and solvent were placed in a reaction vessel.
dipalladium (0) tris(dibenzylidene acetone): 0.24 g (0.26 mmol)
tricyclohexylphosphine: 0.29 g (1.0 mmol)
1,4-dioxane: 8 ml

Then, the reaction mixture was stirred for 15 minutes at room temperature. Subsequently, the following reagents were added to the reaction vessel.
Intermediate 16: 0.80 g (2.6 mmol)
bis(pinacolato) diboron: 0.78 g (3.1 mmol)
potassium acetate: 0.51 g (5.2 mmol)

Then, the reaction solution was stirred for 14 hours while heated at 90° C. under nitrogen flow. Upon the completion of the reaction, the reaction solution was then cooled down to room temperature. After the filtration of the reaction solution, the filtrate solution was subjected to liquid-liquid separation. As a result, an organic phase was separated, which was then washed with water and dried over sodium sulfate. By evaporating the solvent under reduced pressure, a crude product was obtained. The thus obtained crude product was purified by silica gel column chromatography (developing solvent: ethyl acetate/heptane=1/7) to obtain Intermediate 17 (0.63 g, yield: 68%).

### (5) Synthesis of Exemplified Compound D19

The following reagents and solvent were placed in a reaction vessel.
Intermediate 17: 0.50 g (1.4 mmol)
2-methylnaphthalene-1-yl boronic acid: 0.61 g (1.3 mmol)
toluene: 5 ml

Then, the reaction mixture was stirred to dissolve solid matters. Subsequently, the following reagents were added to the reaction vessel.
palladium (II) acetate: 44 mg (0.20 mmol)
2-dicyclohexylphosphino-2′,6′-dimethoxybiphenyl: 0.16 g (0.39 mmol)
tripotassium phosphate: 0.55 g (2.6 mmol)

Then, the reaction solution was stirred for 2 hours while heated at reflux condition under nitrogen flow. The reaction solution was then cooled down to room temperature. After the filtration of the reaction solution, the filtrate solution was subjected to liquid-liquid separation. As a result, an organic phase was separated, which was then washed with water and dried over sodium sulfate. By evaporating the solvent under reduced pressure, a crude product was obtained. The thus obtained crude product was purified by silica gel column chromatography (developing solvent: chloroform/heptane=1/7) to obtain
Exemplified Compound D19 as a pale yellow solid (0.44 g, yield: 54%).

### Example 1

A light-emitting device having a structure as shown in FIG. 3 was produced according to the method described below.

Indium tin oxide (ITO) was formed into a film on a glass substrate (i.e., substrate 1) by a sputtering process to serve as an anode 2. In this case, the thickness of the anode 2 was adjusted to 120 nm. Next, the substrate having the anode 2 formed thereon was subjected to ultrasonic cleaning with acetone and isopropyl alcohol (IPA) in the mentioned order, and then was subjected to washing with purified water followed by drying. Furthermore, the resultant was subjected to UV/ozone cleaning and used as a transparent conductive support substrate.

Next, by mixing Compound 1 shown below as a hole injection material and chloroform, a chloroform solution with concentration of 0.1 wt % was prepared.

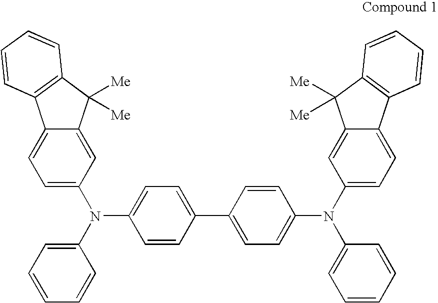

Next, this chloroform solution was dropped onto the above-described anode 2, and the whole was subjected to spin coating initially at the number of revolutions of 500 RPM for 10 seconds and then at the number of revolutions of 1,000 RPM for 40 seconds, whereby a film was formed. After that, the resultant was dried for 10 minutes in a vacuum oven at 80° C., whereby the solvent in the thin film was completely removed. As a result, a hole injection layer 7 was formed. In this case, the thickness of the thus formed hole injection layer 7 was 10 nm.

Next, a hole-transporting layer 3 was formed by forming Compound 2 shown below into a film on the hole injection layer 7 through a vacuum evaporation process. In this case, the thickness of the hole-transporting layer 3 was 15 nm.

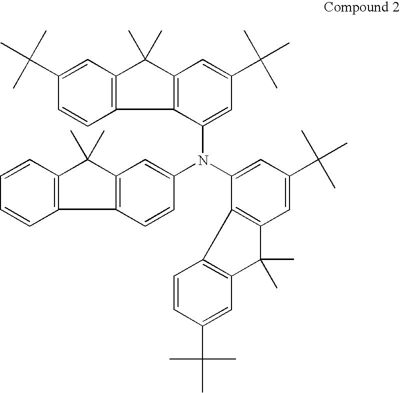

Next, an emission layer 6 was formed by the co-evaporation of Exemplified Compound A2 as a host and Exemplified Compound D1 as a light-emitting dopant through a vacuum evaporation process so as to have the concentration of Exemplified Compound D1 to be 5 wt % in the entire layer. In this case, the thickness of the emission layer 6 was 30 nm. Incidentally, Exemplified Compound A2 and Exemplified Compound D1 were evaporated simultaneously from separate boats.

Next, an electron-transporting layer 4 was provided by forming 2,9-bis[2-(9,9′-dimethylfluorenyl)]-1,10-phenanthroline into a film on the emission layer 6 through a vacuum evaporation process. In this case, the thickness of the electron-transporting layer 4 was 30 nm, the degree of vacuum was 1.0×10⁻⁴ Pa at the time of the evaporation, and the film formation rate was 0.1 nm/sec to 0.3 nm/sec.

Next, lithium fluoride (LiF) was formed into a film on the electron-transporting layer 4 by a vacuum evaporation process to form a first electron injection electrode. In this case, the thickness of the lithium fluoride film was 0.5 nm, the degree of vacuum at the time of the evaporation was 1.0×10⁻⁴ Pa, and the film formation rate was 0.01 nm/sec. Then, aluminum was formed into a film thorough a vacuum evaporation process to provide a second electron injection electrode. In this case, the thickness of the second electron injection electrode was 100 nm, the degree of vacuum at the time of the evaporation was 1.0×10⁻⁴ Pa, and the film formation rate was 0.5 nm/sec to 1.0 nm/sec. According to the procedures described above, an organic light-emitting device was obtained.

A voltage of 4.4 V was applied to the thus obtained device while the ITO electrode (anode 2) was connected to a positive electrode of a power supply and the aluminum electrode (cathode 5) was connected to a negative electrode of the power supply. As a result, it was observed that the device emits blue light having an emission efficiency of 8.9 cd/A and a maximum emission wavelength of 462 nm. Furthermore, a voltage was applied to the device exposed to a nitrogen atmosphere with a current density kept at 100 mA/cm². As a result, the initial luminance was 8461 cd/m² while the luminance after the elapse of 100 hours following the energization was 7408 cd/m², and thus the degradation in luminance was small. Meanwhile, the luminance half-life period with respect to an initial luminance of 1000 cd/m² was 28710 hours.

### Example 2

A device was produced by following the same procedure as in Example 1 with the exception that Exemplified Compound A4 was used instead of Exemplified Compound A2 as a host for the emission layer 6 of Example 1.

When a voltage of 4.8 V was applied to the device of this example, blue light emission having an emission efficiency of 8.3 cd/A and a maximum emission wavelength of 462 nm was observed. Furthermore, a voltage was applied to the device exposed to a nitrogen atmosphere with a current density kept at 100 mA/cm². As a result, the initial luminance was 7908 cd/m² while the luminance after the elapse of 100 hours was 7177 cd/m², thus the degradation in luminance was small.

### Example 3

A device was produced by following the same procedure as in Example 1 with the exception that Exemplified Compound B5 was used instead of Exemplified Compound A2 as a host for the emission layer 6 of Example 1.

When a voltage of 4.5 V was applied to the device of this example, blue light emission having an emission efficiency of 9.3 cd/A and a maximum emission wavelength of 464 nm was observed. Furthermore, a voltage was applied to the device exposed to a nitrogen atmosphere with a current density kept at 100 mA/cm². As a result, the initial luminance was 9286 cd/m² while the luminance after the elapse of 100 hours was 7614 cd/m², and thus the degradation in luminance was small.

### Example 4

A device was produced by following the same procedure as in Example 1 with the exception that Exemplified Compound C7 was used instead of Exemplified Compound D1 as a guest for the emission layer 6 of Example 1 and the concentration of Exemplified Compound C7 was set to 2 wt % with respect to the entire layer.

When a voltage of 4.6 V was applied to the device of this example, blue light emission having an emission efficiency of 8.9 cd/A and a maximum emission wavelength of 483 nm was observed. Furthermore, a voltage was applied to the device exposed to a nitrogen atmosphere with a current density kept at 100 mA/cm². As a result, the initial luminance was 9306 cd/m² while the luminance after the elapse of 100 hours was 8561 cd/m², and thus the degradation in luminance was small.

### Example 5

A device was produced by following the same procedure as in Example 4 with the exception that Exemplified Compound B5 was used instead of Exemplified Compound A2 as a host for the emission layer 6 of Example 4.

When a voltage of 4.6 V was applied to the device of this example, blue light emission having an emission efficiency of 10.4 cd/A and a maximum emission wavelength of 487 nm was observed. Furthermore, a voltage was applied to the device exposed to a nitrogen atmosphere with a current density kept at 100 mA/cm². As a result, the initial luminance was 10766 cd/m² while the luminance after the elapse of 100 hours was 9581 cd/m², and thus the degradation in luminance was small.

### Example 6

A device was produced by following the same procedure as in Example 4 with the exception that Exemplified Compound C14 was used instead of Exemplified Compound C7 as a guest for the emission layer 6 of Example 4.

When a voltage of 4.9 V was applied to the device of this example, blue light emission having an emission efficiency of 6.5 cd/A and a maximum emission wavelength of 465 nm was observed. Furthermore, a voltage was applied to the device exposed to a nitrogen atmosphere with a current density kept at 100 mA/cm². As a result, the initial luminance was 6802 cd/m² while the luminance after the elapse of 100 hours was 6189 cd/m², and thus the degradation in luminance was small.

### Example 7

A device was produced by following the same procedure as in Example 5 with the exception that Exemplified Compound C14 was used instead of Exemplified Compound C7 as a guest for the emission layer 6 of Example 5.

When a voltage of 4.8 V was applied to the device of this example, blue light emission having an emission efficiency of 8.6 cd/A and a maximum emission wavelength of 468 nm was observed. Furthermore, voltage was applied to the device exposed to a nitrogen atmosphere with a current density kept at 100 mA/cm². As a result, the initial luminance was 8966 cd/m² while the luminance after the elapse of 100 hours was 8382 cd/m², and thus the degradation in luminance was small.

### Example 8

A device was produced by following the same procedure as in Example 3 with the exception that Exemplified Compound B3 was used instead of Exemplified Compound B5 as a host for the emission layer 6 of Example 3.

When a voltage of 5.1 V was applied to the device of this example, blue light emission having an emission efficiency of 10.1 cd/A and a maximum emission wavelength of 462 nm was observed. Furthermore, a voltage was applied to the device exposed to a nitrogen atmosphere with a current density kept at 100 mA/cm². As a result, the initial luminance was 9850 cd/m² while the luminance after the elapse of 100 hours was 7687 cd/m², and thus the degradation in luminance was small.

### Example 9

A device was produced by following the same procedure as in Example 7 with the exception that Exemplified Compound B3 was used instead of Exemplified Compound B5 as a host for the emission layer 6 of Example 7.

When a voltage of 5.4 V was applied to the device of this example, blue light emission having an emission efficiency of 9.6 cd/A and a maximum emission wavelength of 466 nm was observed. Furthermore, a voltage was applied to the device exposed to a nitrogen atmosphere with a current density kept at 100 mA/cm². As a result, the initial luminance was 9694 cd/m² while the luminance after the elapse of 100 hours was 9015 cd/m², and thus the degradation in luminance was small.

### Example 10

A device was produced by following the same procedure as in Example 1 with the exception that Exemplified Compound D19 was used instead of Exemplified Compound D1 as a guest for the emission layer 6 of Example 1.

When a voltage of 4.4 V was applied to the device of this example, blue light emission having an emission efficiency of 9.1 cd/A and a maximum emission wavelength of 461 nm was observed. Furthermore, a voltage was applied to the device exposed to a nitrogen atmosphere with a current density kept at 100 mA/cm². As a result, the initial luminance was 8470 cd/m² while the luminance after the elapse of 100 hours was 7538 cd/m², and thus the degradation in luminance was small.

### Example 11

A device was produced by following the same procedure as in Example 2 with the exception that Exemplified Compound D19 was used instead of Exemplified Compound D1 as a guest for the emission layer 6 of Example 2.

When a voltage of 4.8 V was applied to the device of this example, blue light emission having an emission efficiency of 8.4 cd/A and a maximum emission wavelength of 461 nm was observed. Furthermore, a voltage was applied to the device exposed to a nitrogen atmosphere with a current density kept at 100 mA/cm². As a result, the initial luminance was 7915 cd/m² while the luminance after the elapse of 100 hours was 7218 cd/m², and thus the degradation in luminance was small.

### Example 12

A device was produced by following the same procedure as in Example 3 with the exception that Exemplified Compound D19 was used instead of Exemplified Compound D1 as a guest for the emission layer 6 of Example 3.

When a voltage of 4.5 V was applied to the device of this example, blue light emission having an emission efficiency of 9.4 cd/A and a maximum emission wavelength of 463 nm was observed. Furthermore, a voltage was applied to the device exposed to a nitrogen atmosphere with a current density kept at 100 mA/cm². As a result, the initial luminance was 9292 cd/m² while the luminance after the elapse of 100 hours was 7666 cd/m², and thus the degradation in luminance was small.

### Example 13

A device was produced by following the same procedure as in Example 8 with the exception that Exemplified Compound D19 was used instead of Exemplified Compound D1 as a guest for the emission layer 6 of Example 8.

When a voltage of 5.1 V was applied to the device of this example, blue light emission having an emission efficiency of 10.3 cd/A and a maximum emission wavelength of 462 nm was observed. Furthermore, a voltage was applied to the device exposed to a nitrogen atmosphere with a current density kept at 100 mA/cm². As a result, the initial luminance was 9855 cd/m² while the luminance after the elapse of 100 hours was 7785 cd/m², and thus the degradation in luminance was small.

### Comparative Example 1

A device was produced by following the same procedure as in Example 1 with the exception that Compound 3 shown below was used instead of Exemplified Compound A2 as a host for the emission layer 6 of Example 1. Incidentally, Compound 3 can be synthesized by using 4,4,5,5-tetramethyl-2-(pyren-1-yl)-[1,3,2]dioxaborane instead of 2-(7-tert-butyl-pyren-1-yl)-4,4,5,5-tetramethyl-(1,3,2)dioxaborane in Synthesis Example 1 (1).

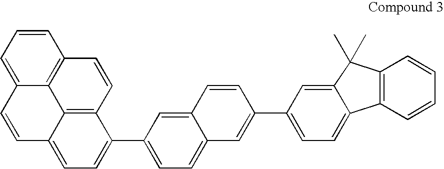

When a voltage of 3.8 V was applied to the device of this comparative example, blue light emission having an emission efficiency of 5.7 cd/A and a maximum emission wavelength of 460 nm was observed. Therefore, the device of this comparative example has a lower emission efficiency than that of the device of Example 1. Furthermore, a voltage was applied to the device exposed to a nitrogen atmosphere with a current density kept at 100 mA/cm² for 100 hours. As a result, the initial luminance was 5930 cd/m² while the luminance after the elapse of 100 hours was 4030 cd/m². Thus, compared to Example 1, the lifetime of this device was shorter.

### Comparative Example 2

A device was produced by following the same procedure as in Example 1 with the exception that Compound 4 shown below was used instead of Exemplified Compound A2 as a host for the emission layer 6 and Compound 5 shown below was used instead of Exemplified Compound D1 as a guest for the emission layer 6 of Example 1.

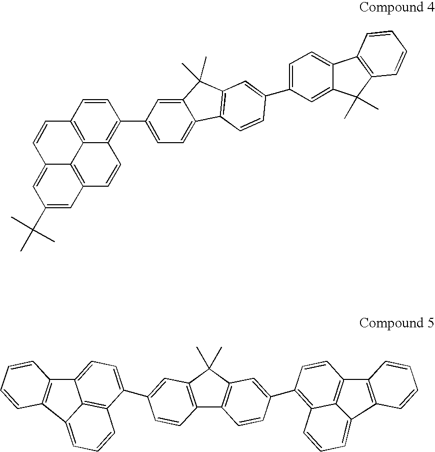

When a voltage of 4.5 V was applied to the device of this comparative example, blue light emission having an emission efficiency of 9.0 cd/A and a maximum emission wavelength of 475 nm was observed. Furthermore, a voltage was applied to the device exposed to a nitrogen atmosphere with a current density kept at 100 mA/cm² for 100 hours. As a result, the initial luminance was 8703 cd/m² while the luminance after the elapse of 100 hours was 5396 cd/m². Thus, compared to the Example 1, the lifetime of this device was shorter.

This application claims the benefit of Japanese Patent Application No. 2008-095106, filed Apr. 1, 2008, which is hereby incorporated by reference herein in its entirety.

1. An organic light-emitting device comprising:
an anode;
a cathode; and
a stacked body which is interposed between the anode and the cathode and comprises a layer which forms a light-emitting region,
wherein the layer which forms the light-emitting region comprises at least one of each of below-mentioned compounds (a) and (b):
(a) a first organic compound represented by the following general formula [1] or general formula [2]: 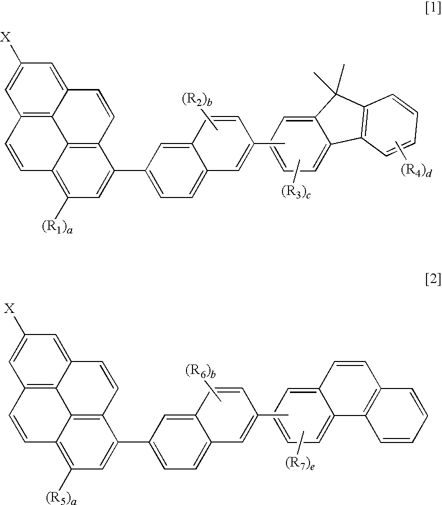
wherein in the general formula [1], R₁ is a substituted or unsubstituted alkyl group; R₂ is a substituted or unsubstituted alkyl group, a substituted or unsubstituted aralkyl group, a substituted or unsubstituted phenyl group or a substituted or unsubstituted aromatic group wherein two rings are fused; each R₃ and R₄, independently, is a halogen atom, a substituted or unsubstituted alkyl group, a substituted or unsubstituted aralkyl group, a substituted or unsubstituted phenyl group, a substituted or unsubstituted aromatic group wherein two rings are fused, or a substituted or unsubstituted heterocyclic group; a is an integer of 0 to 6, and when a is 2 or more, plural R₁'s may be the same or different from each other; d is an integer of 0 to 4, and when d is 2 or more, plural R₄'s may be the same or different from each other; b is an integer of 0 to 3, and when b is 2 or 3, plural R₂'s may be the same or different from each other; c is an integer of 0 to 3, and when c is 2 or 3, plural R₃'s may be the same or different from each other; and X is a substituent represented by the following general formula [A]: 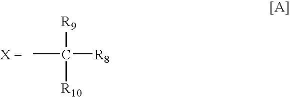
wherein, at least two of R₈, R₉, and R₁₀ are a substituted or unsubstituted alkyl group while the other is a hydrogen atom, and each of R₈, R₉, and R₁₀ may be the same or different from each other, wherein in the general formula [2], R₅ is a substituted or unsubstituted alkyl group; R₆ is a substituted or unsubstituted alkyl group, a substituted or unsubstituted aralkyl group, a substituted or unsubstituted phenyl group or a substituted or unsubstituted aromatic group wherein two rings are fused; R₇ is a halogen atom, a substituted or unsubstituted alkyl group, a substituted or unsubstituted aralkyl group, a substituted or unsubstituted phenyl group, a substituted or unsubstituted aromatic group wherein two rings are fused, or a substituted or unsubstituted heterocyclic group; a is an integer of 0 to 6, and when a is 2 or more, plural R₅'s may be the same or different from each other; b is an integer of 0 to 3, and when b is 2 or 3, plural R₆'s may be the same or different from each other; e is an integer of 0 to 9, and when e is 2 or more, plural R₇'s may be the same or different from each other; and X is a substituent represented by the general formula [A] as defined above;
(b) a second organic compound represented by the following general formula [3] or the general formula [4]: 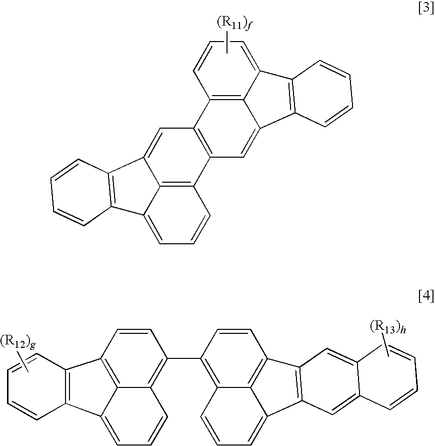
wherein in the general formula [3], R₁₁ is a halogen atom, a substituted or unsubstituted alkyl group, a substituted or unsubstituted aralkyl group, a substituted or unsubstituted aryl group or a substituted or unsubstituted heterocyclic group; f is an integer of 0 to 16, and when f is 2 or more, plural R₁₁'s may be the same or different from each other, wherein in the general formula [4], R₁₂ is a substituted or unsubstituted alkyl group, a substituted or unsubstituted aralkyl group, or a substituted or unsubstituted heterocyclic group; R₁₃ is a halogen atom, a substituted or unsubstituted alkyl group, a substituted or unsubstituted aralkyl group, a substituted or unsubstituted phenyl group, a substituted or unsubstituted aromatic group wherein two rings are fused, or a substituted or unsubstituted heterocyclic group; g is an integer of 0 to 9, and when g is 2 or more, plural R₁₂'s may be the same or different from each other; and h is an integer of 0 to 11, and when h is 2 or more, plural R₁₃'s may be the same or different from each other.

2. The organic light-emitting device according to claim 1, wherein X is a tert-butyl group.
